(19) United States
(12) Patent Application Publication
(10) Pub. No.: US 2025/0237688 A1
(43) Pub. Date: Jul. 24, 2025

(54) Cable Locating System with Data Encoding

(71) Applicant: Metrotech Corporation, Santa Clara, CA (US)

(72) Inventors: Stephen John Petherick, Exeter (GB); Joshua Paul Case, Wellington (GB); John Mark Royle, Exeter (GB)

(21) Appl. No.: 18/419,250

(22) Filed: Jan. 22, 2024

(51) Int. Cl. G01R 31/08; G01V 3/10

(52) U.S. Cl. CPC G01R 31/083; G01V 3/10

(57) ABSTRACT

A line locating system where data encoded onto a locate signal that is transmitted from a transmitter that couples a current onto an underground line and is detected by an above-ground locator, which receives the encoded data. The transmitter encodes data to be transmitted with a bit stream using transitions between adjoining data symbols formed of a first signal having a high frequency and a second signal having a low frequency, the high frequency and the low frequency averaging to a nominal signal of the locate.

### CROSS-REFERENCE(S)

The present disclosure is related to co-pending and commonly-owned U.S. nonprovisional application Ser. No. 18/419,187 filed on the same day, Jan. 22, 2024, which is herein incorporated by reference in its entirety.

### BACKGROUND

### 1. Technical Field

The current application is related to transmission of data on a low frequency magnetic field, for example transmission of data between a transmitter coupled to an underground line and a line locate receiver.

### 2. Discussion of Related Art

Underground utility location and utility installation are common problems for utility companies and local municipalities. Several solutions have been developed to address these problems. In one case, where location of an underground cable or conducting pipeline is needed, an underground pipe and cable location system (often termed a line locator system) can be used. In that system, an above ground receiver detects magnetic signals transmitted by the underground pipe or cable in order to locate the pipe or cable. In another system, a sonde placed within a pipe or as part of a drilling rig can emit electromagnetic radiation that is detected by the above ground receiver to locate the position of the sonde. In some cases, markers can be located proximate the utility and are then used to locate the utility. The current disclosure is directed towards operations that involve locating an underground cable or line.

Underground line locators typically include a transmitter coupled to the underground line to be locating and a remote receiver. Such systems are well known and used within industry sectors who manage buried assets. The principle of emitting an electromagnetic field from an underground line and then locating the line with an above-ground receiver is well used. In the simplest applications the underground line is driven by a coupled transmitter to emit electromagnetic signals that allow phase sensitive measurement of the resulting magnetic fields with the receiver. Receivers engaged in underground line location often include an array of spaced apart antennas (typically between 2 and 6 antennas) and can use the principles of phase coherence to derive directional and distance information to the underground by correlating the measured signals and their relative phases.

Superimposing a low frequency data stream on to a sinewave carrier has some useful and additional applications for a locating system. In particular status information from the transmitter can be communicated to the receiver. However, there are significant problems with the magnitude and phase of the generated magnetic field, which can be emitted by the underground line driven by the transmitter, that can be provide degradation in the location measurement and further provides problems for transmission of digital data using the low frequency magnetic field.

Consequently, there is a need for better digital data communications between a transmitter and an aboveground receiver of the line locating system.

### SUMMARY

A line locating system where data encoded onto a locate signal that is transmitted from a transmitter that couples a current onto an underground line and is detected by an above-ground locator, which receives the encoded data. In accordance to some embodiments a method of transmitting digital data from a transmitter in a line location system includes determining data to be transmitted; generating a bit stream based on the data to be transmitted; and driving an underground line to emit a magnetic field that is modulated with the bit stream, the magnetic signal having a nominal frequency and being formed of a first signal having a high frequency and a second signal having a low frequency, the high frequency being higher than the nominal frequency and the low frequency being lower than the nominal frequency, the nominal frequency being the average frequency of the magnetic signal, wherein the bit stream is modulated onto the magnetic signal by encoding the bit stream into the magnetic signal, where each bit in the bit stream is represented by a transition between adjoining data symbols, each of the data symbols is formed of K repetitions of one of a first state or a second state, where the first state of the pair of states includes M/2 cycles of the nominal frequency with a signal at the high frequency and M/2 cycles of the nominal frequency with a signal at the low frequency, and where a second state of the pair of states includes signals complementary to the first state.

In some embodiments, a transition representing a digital one bit is encoded with a first data symbol of the adjoining symbols formed with the first state and a second data symbol of the adjoining symbols formed with the first state or the first data symbol formed with the second state and the second data symbol formed with the second state. In some embodiments, a transition representing a digital zero bit is encoded with the first data symbol formed with the first state and the second data symbol formed with the second state or the first data symbol formed with the second state and the second data symbol formed with the first state. In some embodiments, the bit stream is formed into a continuous sequence of data frames, each data frame being formed with a separator followed by a synchronization field and one or more data fields, the synchronization field and the one or more data fields separated by a separator. In some embodiments, the one or more of the data fields is encoded with one or more parameters, the each of the one or more parameters include transmitter connection status, temperature, battery state-of-charge, transmitter temperature, vibration, or current strength. In some embodiments, the frame further includes a cyclic redundancy check (CRC) field separated from the last data field by a separator. In some embodiments, the separator bits are zero and the synchronization bits are all ones. In some embodiments, the one or more data fields includes a first data field, a second data field, and a third data field. In some embodiments, the first state includes M/4 cycles of signal at the high frequency followed by M/2 cycles of signal at the low frequency and then M/4 cycles of signals at the high frequency; and wherein the second state includes M/4 cycles of signal at the low frequency followed by M/2 cycles of signal at the high frequency and then M/4 cycles of signals at the low frequency.

In some embodiments, a method of transmitting data from a transmitter coupled to an underground line includes measuring parameters associated with the transmitter with sensors in the transmitter; encoding the parameters into a data frame, the data frame having a sequence of bits, the data frame including a separator followed by a synchronization field and one or more data fields separated by separators; determining a sequence of data symbols to represent the data frame, each of the sequence of bits in the data frame being represented by transitions between adjacent data symbols in the sequence of data symbols, the data symbols each being formed by K repetitions of a first state or formed by K repetitions of a second state, where the first state includes M/2 cycles of a nominal frequency with a high frequency signal at a high frequency and M/2 cycles of the nominal frequency with a low frequency signal at a low frequency, the high frequency being higher than the nominal frequency and the low frequency being lower than the nominal frequency such that the average signal is at the nominal frequency; and driving the underground line to emit a magnetic signal formed with the sequency of data symbols.

In some embodiments, a transmitter includes one or more sensors to measure parameters associated with the transmitter; a line driver coupled to drive an underground line to transmit a magnetic signal; and a processor coupled to the one or more sensors and the driver, the processor configured to receive parameters associated with the transmitter; encode the parameters into a data frame, the data frame having a sequence of bits, the data frame including a separator followed by a synchronization field and one or more data fields separated by separators; determine a sequence of data symbols to represent the data frame, each of the sequence of bits in the data frame being represented by transitions between adjacent data symbols in the sequence of data symbols, the data symbols each being formed by K repetitions of a first state or formed by K repetitions of a second state, where the first state includes M/2 cycles of a nominal frequency with a high frequency signal at a high frequency and M/2 cycles of the nominal frequency with a low frequency signal at a low frequency, the high frequency being higher than the nominal frequency and the low frequency being lower than the nominal frequency such that the average signal is at the nominal frequency; and communicate the input signal corresponding to the sequence of data symbols to the driver.

In some embodiments, a method of receiving digital data from a magnetic signal emitted by a line driven by a transmitter includes receiving a magnetic signal emitted by the under line, the magnetic signal having a nominal frequency and being formed of a first signal having a high frequency and a second signal having a low frequency, the high frequency being higher than the nominal frequency and the low frequency being lower than the nominal frequency, the nominal frequency being the average frequency of the magnetic signal; digitizing the magnetic signal to provide a digitized magnetic signal; and processing the digitized magnetic signal to recover a bit stream, where each bit in the bit stream is represented by a transition between adjoining data symbols, each of the data symbols is formed of K repetitions of one of a first state or a second state, where the first state of the pair of states includes M/2 cycles of the nominal frequency with a signal at the high frequency and M/2 cycles of the nominal frequency with a signal at the low frequency, and where a second state of the pair of states includes signals complementary to the first state.

In some embodiments, processing the digitized magnetic signal to recover the bit stream includes demodulating the magnetic signal to determine phase relative to a nominal signal, the nominal signal being at the nominal frequency; determining a sequence of data symbols; and determining the transitions between adjacent data symbols to determine the bit stream. In some embodiments, demodulating the magnetic signal includes mixing the digitized magnetic signal with a sine and a cosine wave at a carrier frequency to obtain an in-phase and a quadrature signal; filtering the in-phase and the quadrature signal with decimator filters; mixing output signals from the decimator filters with the in-phase and quadrature signals to generate sub-carrier channel signals BX [I] and BX [Q]; combining the sub-carrier signals BX [I] and BX [Q] to form a cross product signal; mixing the cross product signal with a sine and cosine signal at a subcarrier frequency; filtering signals from the from the cross-product with a decimating filter to provide demodulated signals; and generating demodulated magnitude and phase signals from the demodulated signals. In some embodiments, the method further includes combining the sub-carrier channel signals BX [I] and BX [Q] from a plurality of magnetic signals before combining to form the cross product signal. In some embodiments, receiving the magnetic signal includes receiving magnetic signals from a triaxial antenna, the triaxial antenna producing signals related to the magnetic field in two orthogonal horizontal directions and a vertical direction, and wherein combining the sub-carrier channel signals includes generating sub-carrier channel signals for each of the signals; and combining the sub-carrier channel signals for each of the signals to generate the combined sub-carrier channel signals.

In some embodiments, a receiver includes one or more antennas, each of the one or more antennas producing one or more signals related to a magnetic signal emitted from an underground line; an analog front end that receives and digitizes each of the one or more signals from each of the one or more antennas; and a digital processor configured to receive the digitized signals from the analog front end and recovering digital data modulated onto the magnetic field generated by the sonde, wherein the magnetic signal is modulated according to a bit stream, the magnetic signal having a nominal frequency and being formed of a first signal having a high frequency and a second signal having a low frequency, the high frequency being higher than the nominal frequency and the low frequency being lower than the nominal frequency, the nominal frequency being the average frequency of the magnetic signal, and wherein the bit stream is modulated onto the magnetic signal by encoding the bit stream into the magnetic signal, where each bit in the bit stream is represented by a transition between adjoining data symbols, each of the data symbols is formed of K repetitions of one of a first state or a second state, where the first state of the pair of states includes M/2 cycles of the nominal frequency with a signal at the high frequency and M/2 cycles of the nominal frequency with a signal at the low frequency, and where a second state of the pair of states includes signals complementary to the first state. In some embodiments, the digital processor is configured to identify transitions representing a digital one bit that is encoded with a first data symbol of the adjoining symbols formed with the first state and a second data symbol of the adjoining symbols formed with the first state or the first data symbol formed with the second state and the second data symbol formed with the second state. In some embodiments, the digital processor is configured to identify transitions representing a digital zero bit that is encoded with the first data symbol formed with the first state and the second data symbol formed with the second state or the first data symbol formed with the second state and the second data symbol formed with the first state.

In some embodiments of the receiver, the digital processor recovers digital data based on a single signal from one of the antennas. In some embodiments, one of the antennas is a triaxial antenna and the digital processor is configured to recover digital data based on three signals from the triaxial antenna.

These and other embodiments will be described in further detail below with respect to the following figures.

### BRIEF DESCRIPTION OF THE DRAWINGS

FIG. 1 illustrates a line locating system according to some embodiments of the present disclosure.

FIGS. 2A through 2H illustrate a hand-held receiver unit and a user interface, respectively, that can be used to locate an underground line and receive data from the underground line according to some aspects of the present disclosure.

FIGS. 3A through 3E illustrate transmitters of a line locator system according to some aspects of the present disclosure.

FIGS. 4A and 4B illustrate a subcarrier scheme according to some aspects of the present disclosure.

FIGS. 5A and 5B illustrate data symbols according to some aspects of the present disclosure.

FIGS. 6A, 6B, 6C, and 6D illustrates transitions between data symbols to encode data bits according to some aspects of the present disclosure.

FIG. 7 illustrates an example of an unbalanced transition.

FIG. 8A illustrates a data transmission frame according to some aspects of the present disclosure.

FIG. 8B illustrates a particular example of the data transmission frame illustrated in FIG. 8A.

FIG. 8C illustrates a series of data symbols corresponding to the data transmission frame illustrated in FIG. 8B.

FIGS. 9A and 9B illustrates section of the digital signal processing illustrated in FIG. 3B.

FIGS. 10A, 10B, and 10C illustrate aspects of digital data demodulation according to aspects of the present disclosure.

FIG. 11 illustrates operation of a sonde according to some embodiments of the present disclosure.

FIG. 12 illustrates operation of a receiver according to some embodiments of the present disclosure.

The drawings may be better understood by reading the following detailed description.

### DETAILED DESCRIPTION

In the following description, specific details are set forth describing some aspects of the present invention. It will be apparent, however, to one skilled in the art that some embodiments may be practiced without some or all of these specific details. The specific embodiments disclosed herein are meant to be illustrative but not limiting. One skilled in the art may realize other elements that, although not specifically described here, are within the scope and the spirit of this disclosure. Such modifications may include substitution of known equivalents for any aspect of the disclosure in order to achieve the same result in substantially the same way.

Consequently, this description illustrates inventive aspects and embodiments that should not be taken as limiting—the claims define the protected invention. Various changes may be made without departing from scope of this description and the claims. In some instances, well-known structures and techniques have not been shown or described in detail in order not to obscure the invention.

Unless the context requires otherwise, throughout the present specification and claims, the word “comprise” and variations thereof, such as, “comprises” and “comprising” are to be construed in an open, inclusive sense, that is as “including, but not limited to.” Recitation of numeric ranges of values throughout the specification is intended to serve as a shorthand notation of referring individually to each separate value falling within the range inclusive of the values defining the range, and each separate value is incorporated in the specification as it were individually recited herein. Further, individual values provided for particular components are for example only and are not considered to be limiting. Specific dimensional values for various components are there to provide a specific example only and one skilled in the art will recognize that the aspects of this disclosure can be provided with any dimensions. Additionally, the singular forms “a,” “an” and “the” include plural referents unless the context clearly dictates otherwise.

Reference throughout this specification to “one embodiment” or “an embodiment” means that a particular feature, structure or characteristic described in connection with the embodiment is included in at least one embodiment of the present disclosure. Thus, the appearances of the phrases “in one embodiment” or “in an embodiment” in various places throughout this specification are not necessarily all referring to the same embodiment, but may be in some instances. Furthermore, the particular features, structures, or characteristics may be combined in any suitable manner in one or more embodiments.

Embodiments of the present disclosure include a novel method of encoding and decoding digital information onto a low frequency alternating magnetic field, such as that transmitted by an underground sonde or in an underground line location system. Operation with the underground sonde is disclosed in U.S. application Ser. No. 18/419,187, which is concurrently filed with this application and is herein incorporated by reference in its entirety. The sonde described in this application can be any sonde, but a sonde integrated into a steerable boring tube was specifically described. The steerable boring tube can be part of a Trenchless Horizontal Directional Drilling (HDD) system. An above-ground receiver can use two sets of tri-axial antennas to locate the sonde and the sonde can communicate pitch and roll data to the receiver using the encoding and decoding methods described here.

Embodiments of data encoding according to the present disclosure has multiple advantages over existing encoding and decoding methods and can be implemented on any antenna system or antenna array, including arrays with one or more 3D orthogonal axis sensors. Embodiments of cable locating system including this encoding system are described below. Some embodiments of this disclosure provide real-time ‘on-the-fly’ data rather than separated data and command modes.

Embodiments of the present disclosure include a data coding scheme with an identified signal modulation that does not affect the locate field shape. The scheme is described in the context of line location system with any antenna configuration. In particular, communications between a transmitter and a receiver of a line locating system can be facilitated using embodiments of the data coding scheme described in this disclosure.

Line locating receivers that include an array of spaced apart sensors are well known. They can be used to pin-point the position of a buried utility and in some circumstances find a fault condition-typically an impedance fault in the insulating material. Receivers operate various algorithms that can be used to indicate the line position based on the signals received from the spaced apart sensors. With prior knowledge of the characteristics of the transmitter, depth and current can also be calculated.

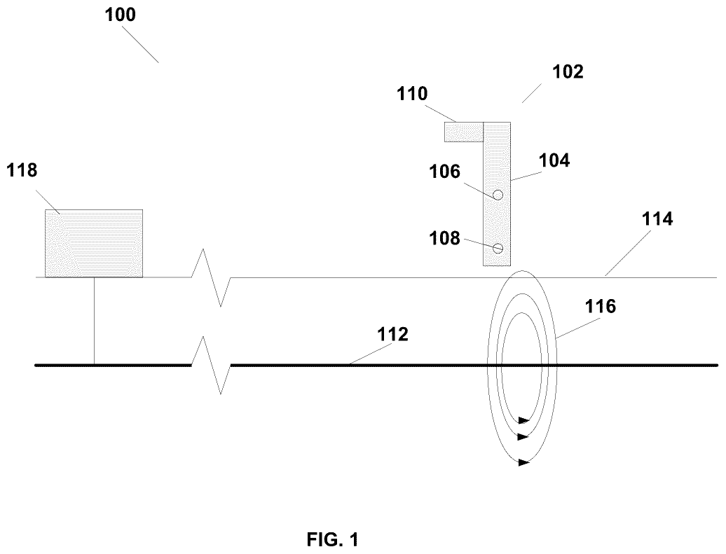

FIG. 1 illustrates a line locating system 100 locating an underground line (or cable) 112. As indicated in FIG. 1, a transmitter 118 is coupled to line 112. Transmitter 118 may be directly coupled to line 112 or may be inductively coupled to line 112. In either case, transmitter 118 drives a current onto line 112, which generates an electromagnetic field 116. The electromagnetic field can be considered a low-frequency electromagnetic field.

Receiver 102 is locating above surface 114 and usually can be handheld by an operator. Typically, receiver 102 includes a wand 104 where one or more antennas are positioned. Antennas in this antenna array can be spaced apart in both horizontal and vertical configurations in order to map magnetic field 116 and each antenna in the array can be 1D, 2D, or 3D antenna configurations. In the example of FIG. 1, antennas 106 and 108 are illustrated and positioned within wand 104. Antennas 106 and 108 can each be 3-D antennas (also referred to as triaxial antennas), 2-D antennas, or 1-D antennas. Further, there can be other antennas in wand 104 that provide signals that can be used to calculate various characteristics of magnetic field 116. A 3-D, or triaxial, antenna can include three individual coils that are positioned relative to one another to measure magnetic fields in three orthogonal directions at a point at the center of the antenna. Signals from antennas 106 and 108 can be processed within receiver 102 and the results displayed on a user interface 110. In some examples, the results can include the determination of the position and depth of line 112 relative to receiver 102.

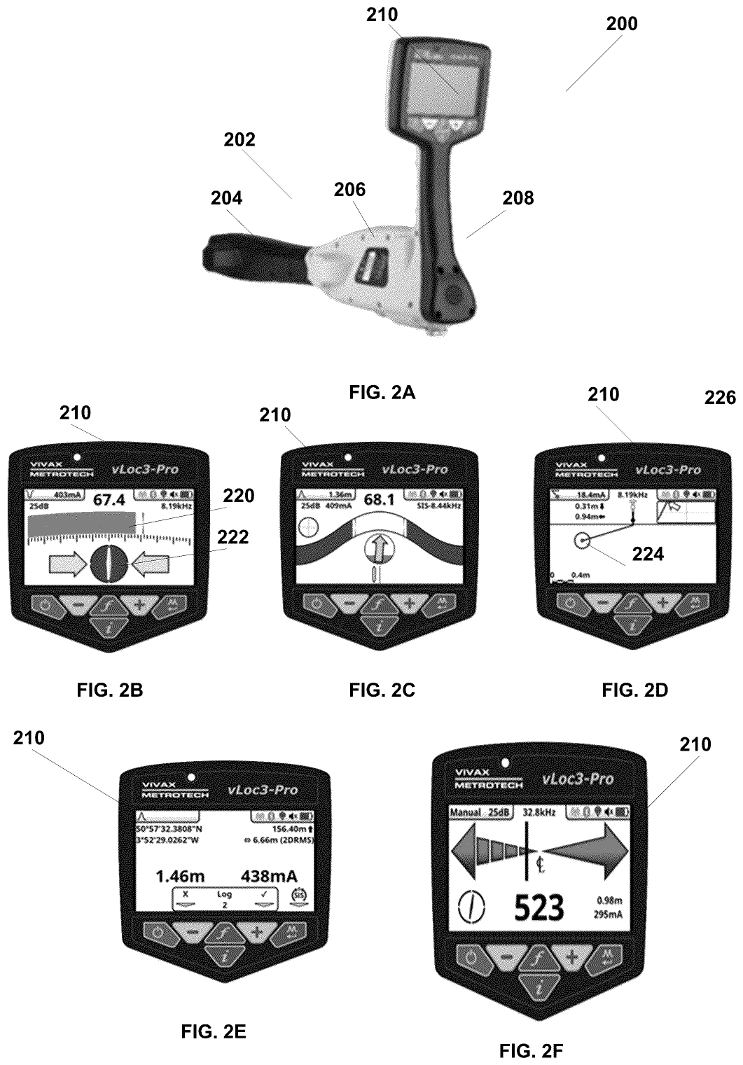

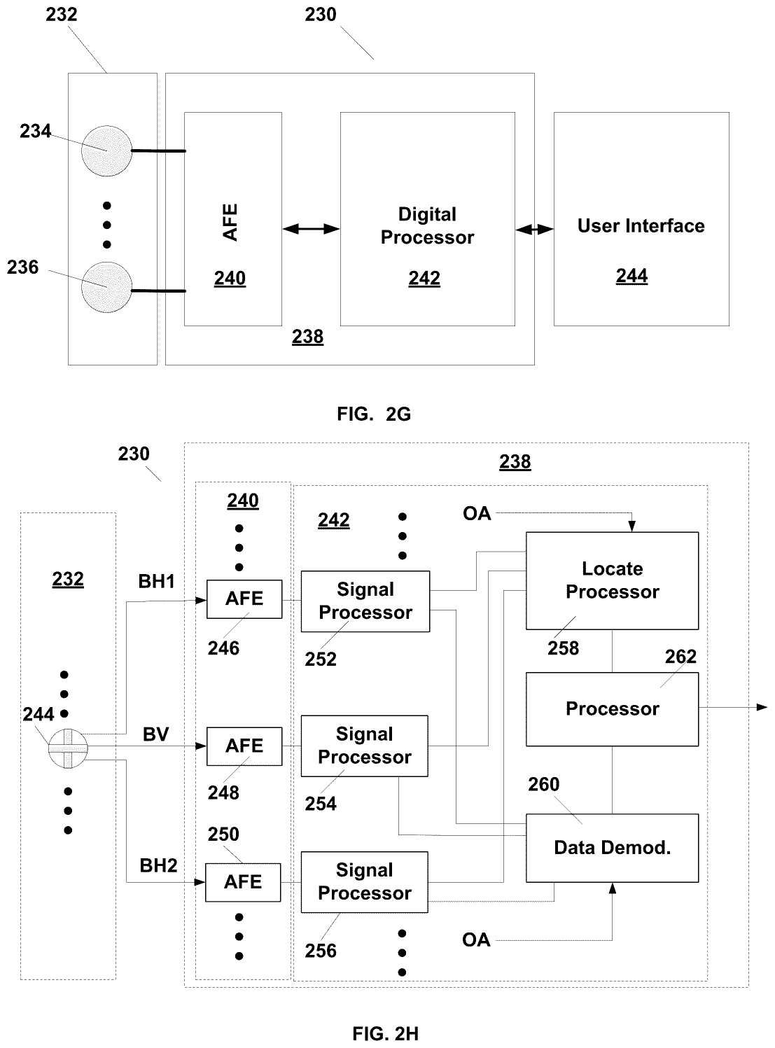

FIGS. 2A through 2H illustrate an example of a receiver 200, that can be an example of receiver 102 as illustrated in FIG. 1. As shown in FIG. 2A, receiver 200 includes a wand 202. Wand 202 includes an antenna section 204 and an electronics section 206. Electronics section 206 can include digital circuitry, microprocessors, ASICs, memory, filters, A/D converters, and all other electronics that process the signals received from antennas housed in antenna section 204. The antennas distributed within antenna section 204, as discussed above, can be combinations of 3-D, 2-D, or 1-D antennas spaced relative to each other in a direction along the length of wand 202 and in a direction perpendicular to wand 202 to provide both vertical and horizontal data to electronics section 206.

Receiver 200 includes a handle section 208 and a user interface 210. Handle section 208 is connected between wand 202 and user interface 210. User interface 210 displays the results of the data processing performed in electronics section 206 of wand 202.

FIGS. 2B through 2F illustrate examples of user interface 210 that demonstrate multiple depictions of the locate data. For demonstrative purposes, the user interface of a Vloc3-Pro receiver (produced by Vivax Metrotech Corp.) in Sonde mode. However, receiver 200 can be adapted to operate according to aspects of the present disclosure.

FIGS. 2B through 2F illustrate various depiction of the results calculated in receiver 200 to assist a user in locating an underground line. In FIG. 2B, for example, illustrates signal strength 220 along with a position indicator. FIG. 2C illustrates more directional data. FIG. 2D indicates where line 224 is relative to the receiver 200 as well as an inground view 226. FIGS. 2E and 2F illustrate other depictions of the data calculated from the antennas in antenna section 204 as well as known data from transmitter 118.

In some embodiments, transmitter can emit electromagnetic fields at a frequency selected from a number of different frequencies (or tones). The locator 200 is tuned to the frequency that the sonde is locating. Consequently, using the data displayed on user interface 210 an operator can, once the electromagnetic field from the underground line 112 is detected, locate the point above the surface under which the underground line 112 is located. Given the signal strength and other characteristics, the depth of the underground line 112 can also be determined.

Consequently, the system that includes receiver 200 gives a clear graphical representation of the position of underground line 112 relative to receiver 200 in a locating system 100 as illustrated in FIG. 1. As illustrated with respect to FIGS. 2B through 2F, user interface 210 of receiver 200 can be configured by the operator to display data to allow the user to locate and map the underground line 112. Embodiments of receiver 200 can also operate in a sonde mode to locate the position of an underground sonde. In either case, there is a need for communication of data between the transmitter and the receiver or between the sonde and the receiver.

Whilst many encoding and decoding systems can convey digital information on a suitable carrier, there are consequential problems to the magnitude and phase of a low frequency magnetic field. These problems cause degradation of the primary purpose of a locating instrument—accurate pin-point locating and depth measurement. In some instances an unwanted phase reversal is detected by one or more of the active antennas, which causes a direction error for a transient period that complicates the locate process.

Consequently, there are identified needs for improvement. Embodiments of the present disclosure address one or more of these needs. Some embodiments of the present disclosure may provide a waveform and data encoding system that runs in continuous wave, without the need to separate a data mode from a general locating mode. Some embodiments of the present disclosure may provide a waveform and data encoding scheme that allows data decoding even when a phase discontinuity or phase reversal on one or more of the orthogonal antennas occurs. Some embodiments of the present disclosure may provide a waveform and data encoding scheme that avoids a drift of the average frequency of the carrier. Some embodiments of the present disclosure may provide a waveform and data encoding scheme that can be phase and/or frequency tracked such that the encoded data waveform does not cause a net phase or frequency drift. Some embodiments of the present disclosure may provide a waveform and data encoding scheme that is balanced over a cycle of the sub-carrier. Some embodiments may of the present disclosure provide a waveform and data encoding scheme that guarantees phase coherence between the transmitter and receiver. Some embodiments of the present disclosure may provide a waveform and data encoding scheme which ensures there is negligible loss of signal-to-noise ratio when compared with a pure sinewave transmission. Some embodiments of the present disclosure may provide a waveform and data encoding scheme which does not impose periodic step response (Heaviside Step Function) on the Digital Signal Processing and associated filter history.

FIGS. 2G and 2H illustrate a receiver 230 according to some embodiments of the present disclosure. As illustrated in FIG. 2G, receiver 230 according to embodiments of the present disclosure can locate and receive digital data from a transmitter such as transmitter 118, which is transmitted on magnetic field 116 as illustrated in FIG. 1. As illustrated in FIG. 2G, receiver 230 can include multiple antennas geometrically distributed within a wand 232. In the example illustrated in FIG. 2G, receiver 230 includes two antennas, antennas 234 and 236, although there may be any number of antennas of any type distributed within wand 232. In some embodiments, antennas 234 and 236 can each be triaxial antennas, each with multiple coils oriented to measure the magnetic field along each of three orthogonal axis. Antennas 234 and 236 detect the magnetic fields that are emitted from line 112.

As is illustrated in FIG. 2G, signals from antennas 234 and 236 in wand 232 are input to electronics section 238. In particular, the signals from antennas 234 and 236 are input to an analog front end (AFE) 240 for analog processing. AFE 240 can receive signals emitted by line 112, provide some analog filtering to the received signals, and digitize the signals with an analog-to-digital converter. A digital processing circuit 242 receives and processes the digitized signals as discussed in further detail below. In particular, digital processing circuit 242 can be any combination of microprocessors, microcomputers, discrete digital circuitry, application specific integrated circuits (ASICs), volatile and non-volatile memory, or other components that perform the functions as described here. In particular, digital processing circuit 242 digitally process signals at the particular frequency used by transmitter 118 and further demodulates and receives digital data that is transmitted with the magnetic fields emitted by line 112 in response to transmitter 118. Digital processing circuit 242 is coupled to user interface 244 to display locate information and transmitter data to a user. Receiver 230 can be similar to receiver 200 illustrated in FIG. 2A and user interface 244 can be similar to that displayed in FIGS. 2B through 2F.

Transmitter 118 and receiver 230 are configured such that transmitter 118 is set to drive line 112 to emit a magnetic field 116 according to a selected tone and receiver 230 is set to detect the magnetic field 116 according to the selected tone. Further, transmitter 118 and receiver 230 are configured to exchange data using the selected tone as is further described below.

In particular, transmitter 118 couples an oscillating current in a narrow bandwidth that constitutes the signal tone onto line 112, which causes line 112 to emit a magnetic field with the same signal tone. The signal tone allows line 112 to be located by a magnetic field locating device (locator) such as receiver 230, as discussed above. Transmitter 118 may be programmed to operate on a plurality of selectable tones. Transmitter 118 and receiver 230 are then tuned to the same tone so that receiver 230 can detect the magnetic field emitted from line 112 and thereby locate line 112.

The signal tone is modulated as discussed below so that transmitter 118 can also transmit digital information to receiver 230. In embodiments of the present disclosure, the modulation is implemented in such a way that there is practically no disturbance to the signal locating tone, and therefore does not interfere with the ability of receiver 230 to locate line 112. Further, since the modulation is provided on the signal locating tone (as a frequency shift key (FSK) based around the signal locating tone), each of the antennas in antenna array 232 provides a signal that includes the modulation. Signals from one or more of the antennas in antenna array 232 can be used to demodulate the modulated signal and recover the transmitted data.

FIG. 2H illustrates a more detailed example of receiver 230 according to some embodiments of the present disclosure. The example illustrated in FIG. 2H shows processing of signals from an example antenna 244, which is one of the antennas in wand 232. In this example, antenna 244 is a triaxial antenna formed from three concentric, orthogonal magnetic field coils to measure the magnetic field strength in three orthogonal directions, although some of the antennas in antenna array 232 may be 1-D or 2-D antennas instead. Antenna 244 produces three signals related to the magnetic field strengths in two orthogonal horizontal directions (BH1 and BH2) and the magnetic field strength in the vertical direction (BV). It should be noted that the terms “horizontal” and “vertical” relate to the physical positioning of receiver 230 and will correspond to geographic horizontal and vertical positions only if receiver 230 is physically oriented accordingly.

The signals BH1, BH2, and BV are input to AFE 240 in electronic section 238. As is illustrated, signal BH1 is input to AFE 246, BV is input to AFE 248, and BH2 is input to AFE 250. As discussed above, each of AFE 246, AFE 248, and AFE 250 provide analog filtering and digitization of the respective signals. The digital signals from AFE 246, 248, and 250 are input to signal processing 252, 254, and 256, respectively. Signal processing 252, 254, and 256 process each of the digitized signals BH1, BV, and BH2, respectively, to recover signal magnitude and phase, which is input to locate processing 258. Locate processing 258 processes the magnitudes and phases of the magnetic field signals detected by antenna 244, as well as the signals received from other antennas in wand 232, to determine the location of line 112 based on those signals. Signals from signal processing 252, 254, and 256 can also be input to data demodulator 330 where the digital data modulated onto the magnetic signals measured by antenna 334 is recovered. In some embodiments, data demodulator 330 recovers the digital data based on one of the signals BH1, BV, or BH2. In some embodiments, data demodulator 330 recovers the digital data based on a combination of all of the signals BH1, BV, and BH2. In some embodiments, data from multiple antennas in wand 302 can be used to recover the digital data.

As is discussed above, transmitter 118 modulates data onto the magnetic field 116. As discussed in further detail below, in the implemented modulation according to the present disclosure, the frequency of the magnetic field generated by transmitter 118 switches between two frequencies, f_{High} and f_{Low}. The first frequency, f_{High}, is slightly above the nominal signal frequency fₙₒₘ of the tone and the second frequency, f_{Low}, is slightly below the nominal signal frequency fₙₒₘ of the tone. In accordance with aspects of the present disclosure, the average frequency f_{avg} over time of the electromagnetic field generated by transmitter 118 is fₙₒₘ.

The phase of the signal relative to the nominal signal tone thus ramps up during transmission of signals at f_{High} and ramps down during transmission of frequencies at frequency f_{Low}. This ramping up and down can be used to construct a data sub-carrier, the phase of which encodes information as explained in more detail below. In this modulation scheme sub-carrier cycle can be composed of M signal tone cycles and can exist in one of two phase states, referred to as positive (P) and negative (N). In general, each of the two phase states includes M/2 signal tone cycles at frequency f_{High} and M/2 signal tone cycles at frequency f_{Low}. The signals at f_{High} and f_{Low} can be distributed in any fashion through the M signal tone cycles and consequently the phase of the signal relative to the nominal signal is the same at the end of the M cycles as it was at the beginning of the M cycles, for example zero. The two phase states are complementary in that where, in the M cycles, the first phase is generating a signal at frequency f_{High} the second phase is generating a signal at frequency f_{Low}, and where the first phase is generating a signal at frequency f_{Low} the second phase is generating a signal at frequency f_{High}.

In some embodiments, for example, the P state consists of M/4 cycles at frequency f_{High} followed by M/2 cycles at frequency f_{Low} and then M/4 cycles at frequency f_{High}. It is thus convenient, but not essential, for M to be a multiple of 4. The N state consists of M/4 cycles at frequency f_{Low} followed by M/2 cycles at frequency f_{High} and then M/4 cycles at frequency f_{Low}. Note that the frequency cycles of f_{high} and f_{low} in the N state are transposed relative to the P state. This represents an example carrier scheme, but other carrier schemes can be devised such that the average frequency over the carrier scheme is the nominal frequency for the tone and the N-state and P-states of the carrier scheme are transposed.

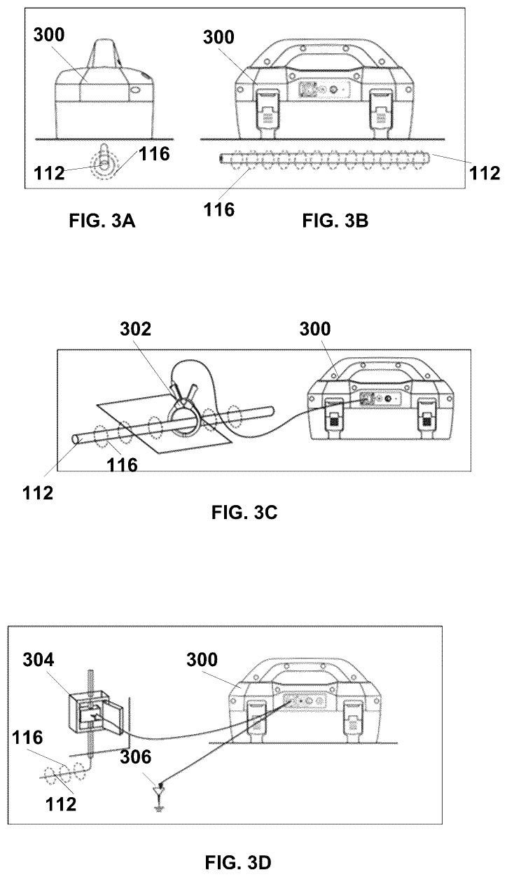

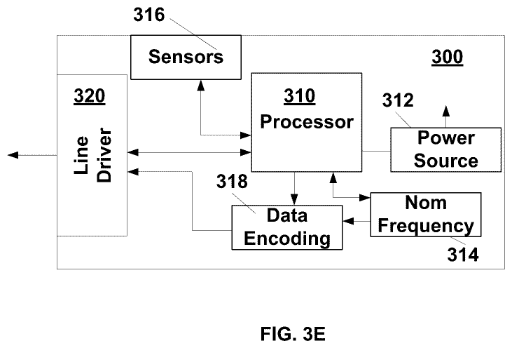

FIGS. 3A through 3E illustrate examples of a transmitter 300 that is an embodiment of transmitter 118 as illustrated in FIG. 1. FIGS. 3A through 3D illustrate various coupling techniques that allow transmitter 300 to couple a current in line 112 such that line 112 emits magnetic field 116 that can be detected by receiver 230 as illustrated in FIGS. 2A through 2I. Transmitter 300 is located remotely from a section of line 112 that is being located by receiver 230, as is illustrated in FIG. 1. Line 112 can be any conductor, for example a cable, a conductive sheathing, a conductive pipe, or other utility.

FIGS. 3A and 3B illustrate a transmitter 300 that inductively couples a current into line 112. In particular, transmitter 300 generates a signal at a particular frequency that induces a current of the same frequency in line 112. In turn, line 112 emits magnetic field 116 at the same frequency along its length. FIG. 3C illustrates coupling between transmitter 300 and line 112 inductively through a coupling signal clamp 302 that clamps around line 112. This is a similar inductive coupling principal that is illustrated in FIGS. 3A and 3B. However, because the coupling is through closed clamp 302, the actual signal coupling is more efficient and tends to be capable of inducing larger signal currents into line 112. FIG. 3D illustrates a transmitter 300 that is directly coupled to line 112 through a junction box 304 and a ground stake 306. In some embodiments, direct connection junction box 304 can be achieved through an impedance matching device using a live plug connector or, in some cases, inductively coupled through a phase-2-phase transformer.

FIG. 3E illustrates a block diagram of an example of transmitter 300. As illustrated, transmitter 300 includes a power source 312 that provides power. Power source 312 can, for example, be a battery or may be coupled to an external source. Further, transmitter 300 includes a frequency generator 314 that provides a nominal frequency signal. Additionally, transmitter 300 includes a line driver 320 that couples a current signal onto an underground line 112, for example as is illustrated in FIGS. 3A through 3D and discussed above.

Transmitter 300 can be controlled by a processor 310. Processor 310 can include any combination of microprocessors, microcomputers, discrete digital circuitry, application specific integrated circuits (ASICs), volatile and non-volatile memory, or other components to perform as described here. Processor 310 is coupled to receive data from one or more sensors of sensors 310, from power source 312, from frequency generator 314, and from line driver 320. Processor 310 further may provide instructions to line driver 320 and frequency driver 314 that is capable of setting the nominal frequency and the mode of coupling. Processor 310 also compiles data to be transmitted to receiver 230 on magnetic field 116 and controls data encoding 318 to provide the correct frequencies to line driver 320 to transmit the data. The data encoding scheme according to embodiments of the present disclosure is further described below.

Any data that may be collected by processor 310 can be transmitted according to embodiments of the present disclosure. For example, in some embodiments encoding identification data regarding the line transmitter can be transmitted. Additionally, transmitter 300 may include sensors 316. In some embodiments, sensor 316 may be configured to sense temperature, line impedance, ground impedance, battery life, RMS vibration, or other environmental data. Additionally, the line transmitter connection status can be transmitted. In that fashion, receiver 230 may be aware of the coupling characteristics as described above (e.g., coupling as illustrated in FIGS. 3A through 3D above). The characteristics of the power source 312 can also be transmitted as well as the strength of the current signal provided on line 112.

In some embodiments, receiver 230 may receive encoding identification from either a transmitter such as transmitter 300 or a sonde and switch between line locate modes and sonde locate modes accordingly. As is further described in the co-filed application Ser. No. 18/419,187, a sonde may also use data encoding as described here to communicate data with receiver 230, including magnetic field strengths and other data.

Consequently, in accordance with embodiments of the present disclosure, a line locating receiver includes at least two physically separated antennas, which may be triaxial antennas, that can receive a phase coherent low frequency magnetic field emanating from an underground line. In some embodiments, the line locating receiver can switch between detecting the magnetic field emanating from a line and the electromagnetic field generated by a sonde. As is discussed, a digital bit stream is encoded on the magnetic field. In particular, the digital bit stream is encoded such that it does not compromise or degrade the phase coherence of the magnetic field signal used to locate the line or sonde. The digital data can be received on any of the available antenna channels or combinations of any of the available antenna channels. Further, the digital data is processed in receiver 230 in real time, without the need for separated command and data modes for data processing.

In some embodiments, the digital information may represent the Temperature and Battery status of transmitter 118. Further, the data information may include the measured complex ground impedance of a buried utility with respect to earth. The digital information may indicate the connection mechanism between a Line Transmitter and a buried utility. In some cases, the digital information may indicate an Identity Code for the transmitter 300. Consequently, that data that may be transmitted from transmitter 300 to receiver 230 can include, for example, transmitter identification, transmitter connection status, transmitter temperature, transmitter battery charge, transmitter current strength, RMS vibration, or other data.

In the case of a sonde, for example, the digital information may represent the Magnetic Field Strength of the emitting Sonde, the pitch and roll angle of the sonde, battery strength, magnetic field strength, identification, or other data.

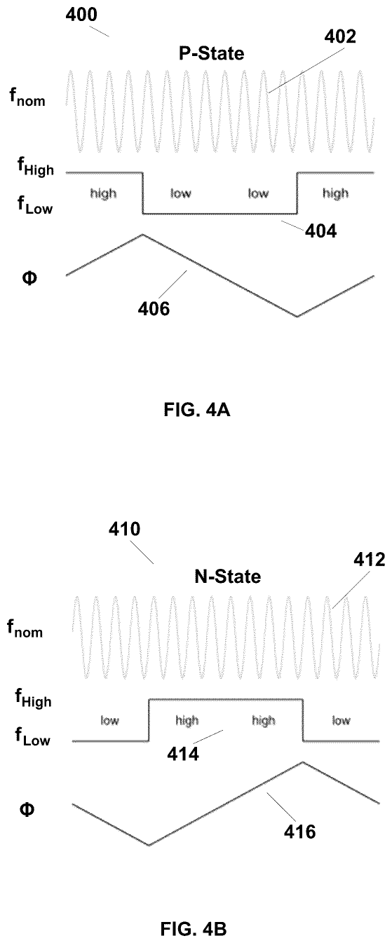

FIGS. 4A and 4B illustrate states P and N for a subcarrier scheme with M=16 cycles, as described above. As illustrated in FIG. 4A, a P-state 400 is illustrated. Nominal signal 402 with frequency fₙₒₘ is illustrated for reference. The actual signal frequency 404 illustrates that, in P-state 400, there are four cycles (M/4) where the signal has frequency f_{high}, then eight cycles (M/2) where the signal has frequency f_{low}, and another four cycles (M/4) where the signal has frequency f_{high}. The phase (ϕ) 406 of the actual signal relative to nominal signal 402 then illustrates that during cycles where the signal is operating at frequency f_{high} the phase increases and during cycles where the signal is operating at frequency f_{low} the phase decreases. As a consequence, during P-State 400 the phase reaches a peak after the first cycles with the signal at frequency f_{high}, a low after the cycles where the signal is at frequency f_{low}, and returns to the starting phase (which may be 0) after the second cycle with the signal at frequency f_{high}. Consequently, the distribution of cycles with f_{High} and f_{Low} is symmetric so that there is no overall change in the phase over the M cycles of the P-state subcarrier scheme.

FIG. 4B illustrate an N-state 410 according to some embodiments of this disclosure. Nominal signal 412 with frequency fₙₒₘ is illustrated for reference. The actual signal frequency 414 illustrates that, in N-state 412, there are four cycles (M/4) where the signal has a frequency f_{Low} followed by eight cycles (M/2) where the signal has a frequency f_{High}, again followed by four cycles (M/4) where the signal has a frequency f_{low}. The phase (ϕ) 416 of the signal relative to nominal signal 412 then illustrates that during cycles where the signal is operating at frequency f_{Low} the phase decreases and during cycles where the signal is operating at a frequency f_{High} the phase increases. As a consequence, during N-state 412 the phase reaches a minimum after the first cycles with the signal at frequency f_{Low}, a high after the cycles where the signals is at frequency f_{High}, and returns to the starting phase (which may be 0) after the final cycles with the signal at frequency f_{Low}. Consequently, the distribution of cycles with f_{High} and f_{low} is symmetric so that there is no overall change in the phase over the M cycles of the subcarrier scheme.

It should be noted that the example illustrated in FIGS. 4A and 4B is for illustration only. The number of cycles M that can be used in the N-state and P-state can be any value. Further, there may be a different subcarrier scheme (i.e. different sequence of f_{High} and f_{Low} signals). The scheme can be expanded or modified to have different numbers of cycles or a different distribution of f_{High} and f_{low}. However, in accordance to embodiments of the present disclosure, the sequence of f_{High} and f_{Low} cycles are symmetric so that at the conclusion of the subcarrier scheme the change in phase throughout the M cycles of the scheme is zero (0). Furthermore, the average frequency of the signal is at from throughout transmission of data.

In accordance with some embodiments of the present disclosure, data symbols can be transmitted using a series of successive subcarrier schemes. In accordance with embodiments of the present disclosure, each transmitted data symbol can be indicated with an integer number K of identical sub-carrier cycles, that is either K cycles of P or K cycles of N. Consequently, in order to transmit data the signal tone frequency fₙₒₘ is a factor of K*M higher than the data symbol rate (i.e. fₙₒₘ=α*K*M, where a is the data symbol rate).

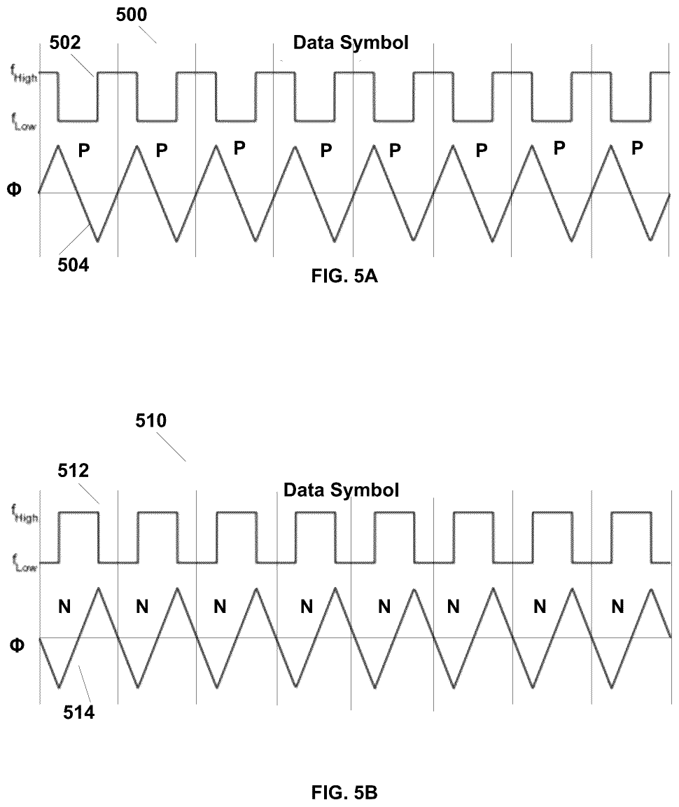

FIGS. 5A and 5B illustrate data symbols represented in K repetitions of P states or K repetitions of N states, respectively. In the example illustrated in FIGS. 5A and 5B, K is eight (8). For example, a first data symbol is formed from P states and a second data symbol can be formed of N states. In general, K can be any integer. FIG. 5A illustrates a data symbol 500. In particular, the symbol frequency 502 that includes K=8 P-states 400 as illustrated in FIG. 4A, for example. The phase change 504 indicates the phase change of the signal over the K*M cycles of the data symbol. As indicated, the phase change 504 is symmetric across the symbol 500 and results in no overall phase change (Δϕ=0).

Similarly, FIG. 5B illustrates a data symbol 510 formed with K=8 N-states. The symbol frequency 502 includes K=8 N-states 410 as illustrated in FIG. 4B, for example. The phase change 514 indicates the phase change of the signal over the K*M cycles of the data symbol. As indicate, the phase change 514 is symmetric across data symbol 510 and results in no overall phase change (Δϕ=0).

In accordance with embodiments of the present disclosure, individual data bits are transmitted at the symbol rate a based on the boundary between successive data symbols. In some embodiments, a zero bit can be represented by a phase transition between two successive data symbols (P-N or N-P) and a one bit is represented by no phase transition between successive data symbols (P-P or N-N). In other words:
0 (zero)=P-N or N-P transition between successive data symbols; and
1 (one)=P-P or N-N transition between successive data symbols.

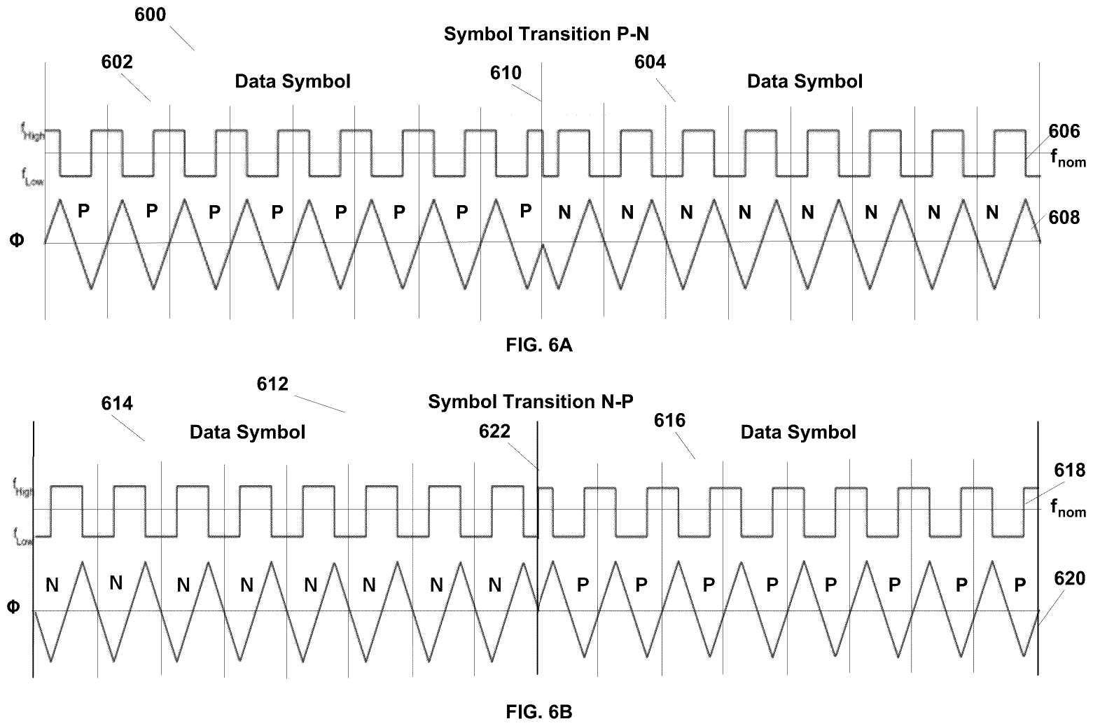

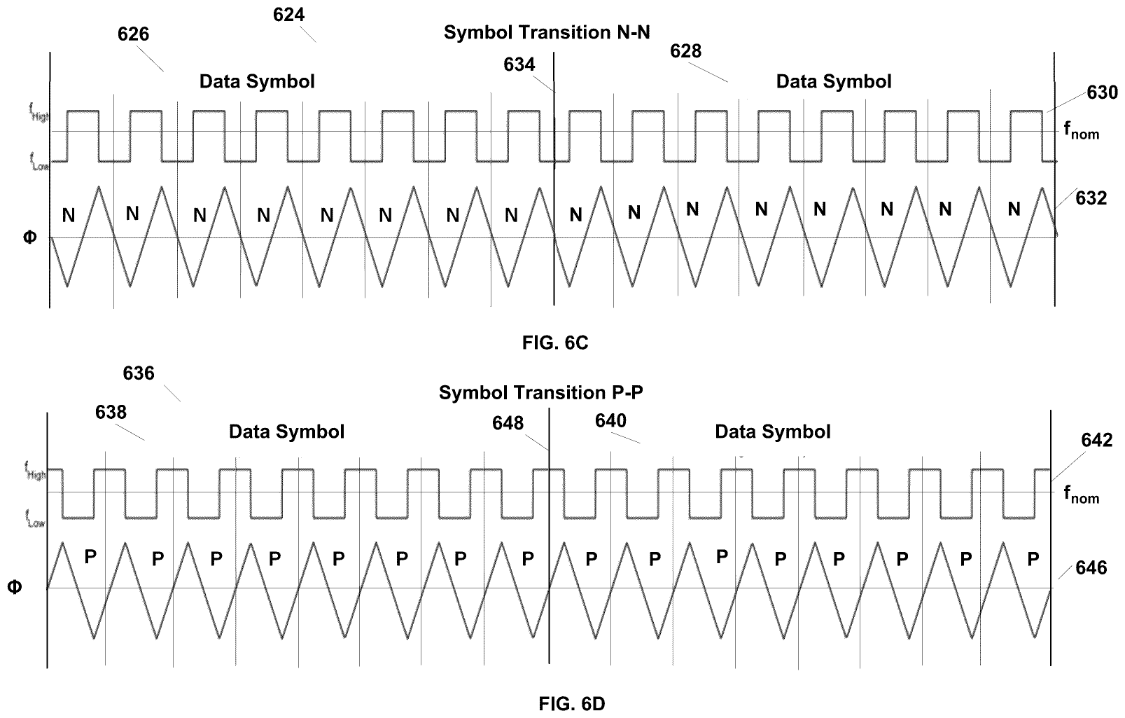

FIGS. 6A through 6D illustrate depictions of the various transitions used to represent digital bits according to some embodiments of the present disclosure. FIG. 6A illustrates a data symbol transition 600 from P-state symbols to N-state symbols, which as discussed above can represent a digital 0 bit. FIG. 6A illustrates two successive data symbols, symbols 602 and 604. Data symbol 602 is a data symbol 500 as shown in FIG. 5A, which includes K=8 number of successive P-states 400 as illustrated in FIG. 4A. Data symbol 604 is a data symbol 510 as shown in FIG. 5B, which includes K=8 number of successive N-states 410 as shown in FIG. 4B. FIG. 6A illustrates the frequency of the signal 606 (f_{High} and f_{Low}) and the phase 608 relative to the nominal signal. Data symbol 602 ends and data symbol 604 begins at transition 610. As shown in FIG. 6A, data symbol 602 (that includes successive P-states) smoothly transitions to data symbol 604 (that includes successive N-states) at transition 610. As is illustrated, there are no discontinuities in phase 608. Further, there is no overall shift in phase 608 through the transition such that the phase at the start of data symbol 602 is the same as that at the end of data symbol 604 (i.e., Δϕ-0).

FIG. 6B illustrates a data symbol transition 612 from N-state symbols to P-state symbols, which as discussed above can represent a digital 0 bit. FIG. 6B illustrates two successive data symbols, symbols 614 and 616. Data symbol 614 is a data symbol 510 as shown in FIG. 5B, which includes K=8 number of successive N-states 410 as illustrated in FIG. 4B. Data symbol 616 is a data symbol 500 as shown in FIG. 5A, which includes K=8 number of successive P-states 400 as shown in FIG. 4A. FIG. 6B illustrates the frequency of the signal (f_{High} and f_{low}) 618 and the phase 620 relative to the nominal signal. Data symbol 614 ends and data symbol 616 begins at transition 622. As shown in FIG. 6B, data symbol 614 (that includes successive N-states) smoothly transitions to data symbol 616 (that includes successive P-states). As is illustrated, there are no discontinuities in phase 620. Further, there is no overall shift in phase 620 through the transition such that the phase at the start of data symbol 614 is the same as that at the end of data symbol 616 (i.e., Δϕ=0).

FIG. 6C illustrates a data symbol transition 624 from N-state symbols to N-state symbols, which as discussed above can represent a digital 1 bit. FIG. 6C illustrates two successive data symbols, symbols 626 and 628. Both data symbol 626 and data symbol 628 are illustrated as data symbol 510 as shown in FIG. 5B, which includes K=8 number of successive N-states 410 as shown in FIG. 4B. FIG. 6C illustrates the frequency of the signal (f_{High} and f_{Low}) 630 and the phase 632 relative to the nominal signal. Data symbol 626 ends and data symbol 628 begins at transition 634. As shown in FIG. 6C, data symbol 626 (that includes successive N-states) smoothly transitions to data symbol 628 (that also includes successive N-states). As is illustrated, there are no discontinuities in phase 632. Further, there is no overall shift in phase 632 through the transition such that the phase at the start of data symbol 626 is the same as that at the end of data symbol 628 (Δϕ=0).

FIG. 6D illustrates a data symbol transition 636 from P-state symbols to P-state symbols, which as discussed above can represent a digital 1 bit. FIG. 6D illustrates two successive data symbols, symbols 638 and 640. Both data symbol 638 and data symbol 640 are illustrated as data symbol 500 as shown in FIG. 5A, which includes K=8 number of successive P-states 400 as shown in FIG. 4A. FIG. 6D illustrates the frequency of the signal (f_{High} and f_{Low}) 642 and the phase 646 relative to the nominal signal. Data symbol 638 ends and data symbol 640 begins at transition 648. As shown in FIG. 6D, data symbol 638 (that includes successive P-states) smoothly transitions to data symbol 640 (that also includes successive P-states). As is illustrated, there are no discontinuities in phase 646. Further, there is no overall shift in phase 646 through the transition such that the phase at the start of data symbol 638 is the same as that at the end of data symbol 640 (Δϕ=0).

The data transmission methods according to embodiments of this disclosure have several appealing features which result in the signal tone being undisturbed for practical purposes. In particular, as is indicated in FIGS. 6A through 6D, there are no phase discontinuities such as can occur with a simple FSK scheme. Further, as shown in FIGS. 6A through 6D, the signal waveform is balanced in that the total durations of signals at frequency f_{High} and signals at frequency f_{Low} do not vary with data modulation. This results in the average signal tone frequency being data independent and is always fₙₒₘ.

As is illustrated in FIGS. 6A through 6D, the signal waveform is balanced in the sense that there are no overall shifts in relative phase. As pointed out above, phase 608 of FIG. 6A, phase 620 of FIG. 6B, phase 632 of FIG. 6C, and phase 646 of FIG. 6D, the peak-to-peak phase deviation remains constant and shows no phase discontinuities or phase shifts through data transition. Further, as is illustrated in signal frequency 606 of FIG. 6A, signal frequency 618 of FIG. 6B, signal frequency 630 of FIG. 6C, and signal 642 of FIG. 6D has properly balanced f_{High} and f_{Low} that the overall average signal frequency is fₙₒₘ. The sub-carrier frequency for data transmission can also easily be set outside the signal tone locating band while still allowing a useful data rate.

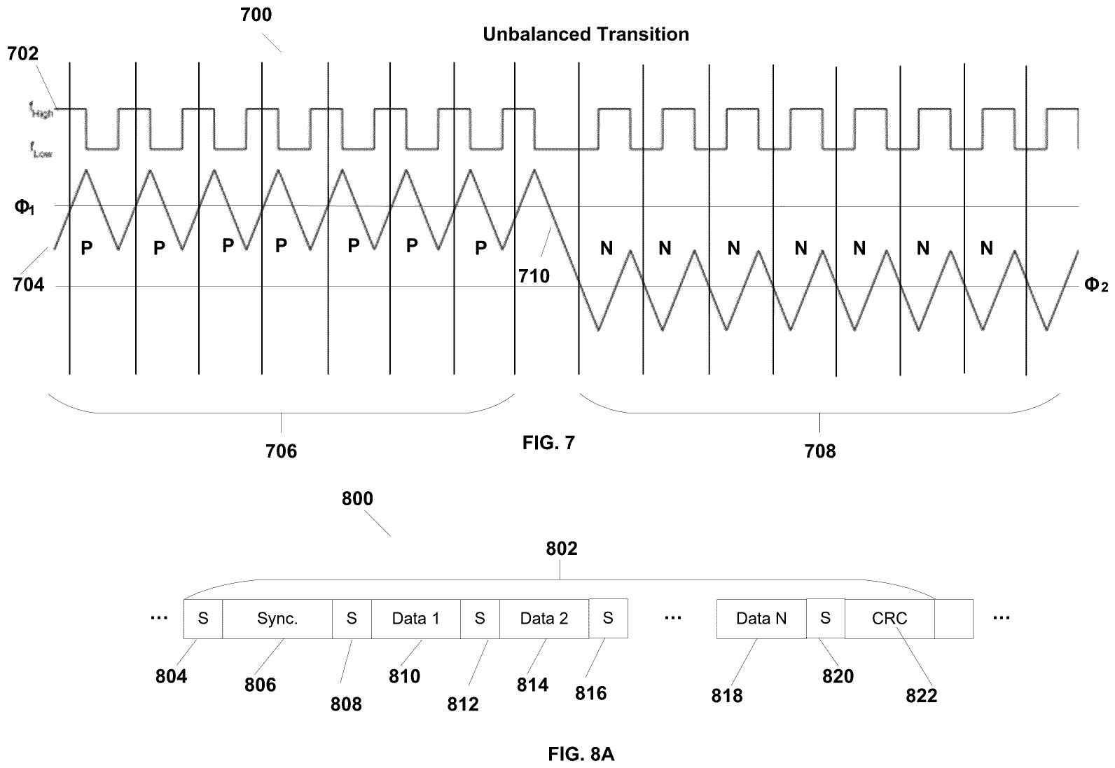

FIG. 7 illustrates an example of an unbalanced transition 700 between a series of P-states to a series of N-states. As shown in FIG. 7, signal frequency 702 and phase 704 illustrate the transition, similar to what would occur in, for example, Manchester coding. Signal frequency 702 and phase 704 illustrate a first section 706 that exhibits a series of P-state signals as illustrated above in FIG. 4A and a second section 708 that exhibits a series of N-state signals as illustrated above in FIG. 4B. First section 706 and second section 708 are separated by transition section 710.

As is illustrated in transition section 710, however, in transition section 710 the signal frequency 702 shows that the signal is at frequency f_{Low} for a period of time long enough that the average frequency shifts from frequency ϕ₁ to frequency ϕ₂. This is a shift in the average phase of Δϕ=ϕ₂-ϕ₁. This phase shift disturbs the detected signal tone due to the unfortunate timing of the transition. The resulting phase shift Δϕ and the disturbance in the average frequency results in signal degradation.

The transition illustrated in FIG. 7 can, for example be, Manchester coding of 8 ones followed by 8 zeros (or vice versa depending on polarity). It will clearly cause a data dependent disturbance of the detected signal tone as discussed above

The transitions illustrated in FIGS. 6A through 6D, as discussed above, provide for smooth transitions with no shifts in the average phase throughout transmission of data. Further, the average frequency of the signal remains at fₙₒₘ. Consequently, the sub-carrier frequency can also easily be set outside the signal tone locating band while still allowing a useful data rate.

An advantage of using transitions to mark data zeros is as illustrated in FIGS. 6A and 6B is that the receiving device, receiver 230, does not need to determine the absolute phase of the sub-carrier (or indeed the signal tone) since P-to-N and N-to-P transitions are equivalent. On the other hand, if no transitions at all are detected, as is illustrated in FIGS. 6C and 6C, then this represents a stream of data ones. In some embodiments of the framing structure, this situation may not be recognized as valid data.

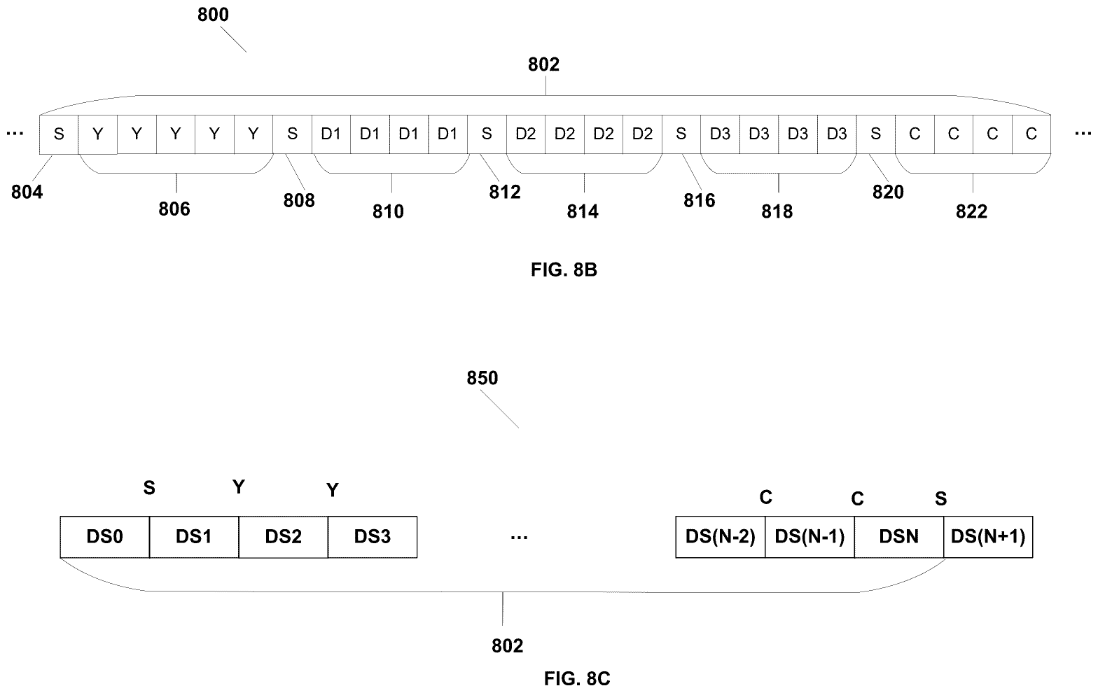

The decoding stage, which can be implemented digitally in digital processing 242 or may have components provided in both AFE 240 and Digital processing 242 of receiver 230 as illustrated in FIGS. 2G and 2H, is dependent on a suitably designed data framing scheme. Embodiments of the present disclosure deploy a well-matched data framing scheme. Characteristics of such a data framing scheme can include the following: maximizing the data opportunity (the information bandwidth being sufficient to effectively transmit data); maximizing the Signal-to-Noise Ratio (SNR) and consequently the transmission distance that can be attained; allowing the decoding system to latch on to the demodulated signal, regardless of where it may start in the data frame; and guaranteeing phase markers to assist in synchronizing to the data frames. A particular example of such a frame is illustrated in FIGS. 8A and 8B.

FIG. 8A illustrates a bit stream 800 using the bit representations as illustrated in FIGS. 6A through 6D. Bit stream 800 may include a series of data frames 802 as is further illustrated. In some embodiments, bit stream 800 may be a continuous series of data frames 802. In some embodiments, bit stream 800 may have sporadic sequences of one or more data frames 802. As illustrated in FIG. 8A, data frame 802 can include any number of individual bits, starting with a separator bit 804 followed by a synchronization field 806, and one or more data fields data 1 810 through data N 818. The synchronization field 806 and the one or more data fields (data 1 810, data 2 814, through data N 818) are each separated by a separator (separators 808, 812, and 816, respectively. In some embodiments, a cyclic redundancy check (CRC) field, separated by separator 820 from the last data field data N 818, finishes data frame 802. The separator 804 followed by the synchronization field 806 provides a unique identifier that the receiver can use to identify the start of data frame 802. Consequently, synchronization field 806 is configured such that that particular sequence of bits cannot recur elsewhere in data frame 802.

Data frame 802 can include any number of data fields that can be used to send data. Particular parameters can be transmitted in one or more data fields. For example, transmitter ID, battery charge, current, temperature or other parameters can each be encoded across one or more of the data fields in data frame 802.

For illustrative purposes, a particular example of data frame 802 is illustrated in FIG. 8B. In the example illustrated in FIG. 8B, frame 802 includes 26 bits, however as discussed above frame 802 may include any number of overall bits. As discussed above, frame 802 starts with a separator followed by a synchronization field, one or more data bit fields, and a cyclic redundancy check (CRC) field, each separated by a separator. In some embodiments, the synchronization field includes a different number of bits than are included in the one or more data bit fields or the CRC field so that the synchronization field is easily distinguishable within frame 802.

In the particular example of bit frame 802 illustrated in FIG. 8A, bit frame 802 starts with a separator bit 804 followed by synchronization bits 806, designated as Y in FIG. 8A. There may be any number of synchronization bits in frame 802, but in the example illustrated in FIG. 8B there are five (5) synchronization bits 806. Synchronization bits 806 are followed by another separator 808 and then data field 810, which includes four bits labeled D₁. Data field 810 is followed by another separator 812 and then another data field 814, which includes four bits labeled D₂. Data field 814 is followed by a separator 816 and a third data field 818, which includes four bits labeled D₃. Data field 818 is followed by a separator 820 and CRC field 822, which includes four bits labeled C. As is illustrated in FIG. 8B, separators 804, 808, 812, 816, and 820 can consist of a single bit, which in some embodiments is a 0 as illustrated in FIGS. 6A and 6B. Synchronization 806 can be a five-bit field. In some embodiments, the five bits can all be a 1 as is illustrated in FIGS. 6C and 6D. Data bits 810, 814, 818, and CRC field 822 can be four-bit fields that will be represented as a combination of zeros and ones representing the transmitted data. In some embodiments, data can be sent continuously in fixed length frames with no gaps between frames 802. In the particular example of the 26-bit frame illustrated in FIG. 8B, the data frame 802 can have the following format:

SYYYYYSD₁D₁D₁D₁SD2D₂D₂D₂SD3D₃D₃D₃SCCCC.

In a particular frame 802 structure applicable to some applications is provided in the following table:

| Item | Data Element | Resource | |
|---|---|---|---|
| Separator | S | 1 | bit |
| Sync | YYYYY | 5 | bits |
| Separator | S | 1 | bit |
| Data | D₁D₁D₁D₁ | 4 | bits |
| Separator | S | 1 | bit |
| Data | D₂D₂D₂D₂ | 4 | bits |
| Separator | S | 1 | bit |
| Data | D₃D₃D₃D₃ | 4 | bits |
| Separator | S | 1 | bit |
| CRC | CCCC | 4 | bits |
| Total | | 26 | bits |

As discussed above, data fields D₁, D₂, and D₃ can be used to depict any of the data related to line location as described above.

In some embodiments, the separator fields are a zero bit. The regular insertion of zero separator bits (phase inversion) allows the receiving device 300 to synchronize with the bit stream. The sync field 806 includes a different number of bits than is provided in data fields 810, 814, 818 or CRC field 822. In the example illustrated in FIG. 8B, sync flag 806 includes five (5) bits, all of which are ones, while data fields 810, 814, 818 and CRC field 822 each include four (4) bits. This guarantees that the sync field 806 (for example of five ones) can only occur at the start of a frame 802 and cannot be emulated in any of the data fields 810, 814, 818, or CRC 822. Consequently, frame 802 can be used to send data as detected by sensors 316 of a transmitter 300.

In particular, the data can be coded in multiple data fields in data fields. Although the current example data frame 800 includes three data fields (810, 814, and 818), as illustrated in FIG. 8A data frame 800 can include any number of data fields, each of which can include any number of bits.

The CRC field 822 allows for an appended CRC. In examples where the sync field 806 is five-bits and each of data fields 810, 814, and 818 are four bits, the transmitter 300 computes the CRC on the 17 data bits from first separator 804 to separator 820, i.e. the whole frame apart from the CRC itself and the separator bits. In the particular example provided here, the CRC field 822 can be four bits generated by a polynomial, for example the polynomial 0×03=×4+×+1. In some embodiments, there is no seed value or XOR. Consequently, the CRC of an error-free 21-bit frame equals zero.

FIG. 8C illustrates that data symbol stream 850 that corresponds with the data frame 802 illustrated in FIG. 8B. As illustrated in FIG. 8C, data symbol stream 850 begins at symbol DS0, which is also the last data symbol in the previously transmitted frame 802. The separator 804, which as discussed above is a 0, is illustrated in the data symbol transition between DS0 and DS1 according to that discussed above with FIGS. 6A and 6B (i.e. if DS0 is a data symbol of N-states then DS1 is a data symbol of P-states and if DS0 is a data symbol of P-states then DS1 is a data symbol of N-states). Since synchronization field 806 is a series of 1's, then DS2 through DS6 are all the same as DS1. DS6 to DS7, however, designates separator 808, which is a 0 bit, and therefore DS7 is a data symbol that is the complement of DS6 (i.e. if DS6 is a data symbol of N states, then DS7 is a data symbol of P states whereas if DS6 is a data symbol of P states, then DS7 is a data symbol of N states). The data symbols in data symbol series 850 are then designated to corresponded to the remaining bits in data frame 802 according to the bit representations illustrated in FIGS. 6A through 6D. The last data symbol in data frame 802 is then DSN, which in a 26 bit data frame N=26. The last data frame DSN is then the data frame that starts the next transmitted frame 802, where separator 804 of the next frame is represented by the transition between data symbols DSN and DS (N+1).

Consequently, a receiver can synchronize with the data transmission. The receiver locates a separator 804 followed by synchronization field 806 in the bit stream, which will identify the beginning of a data frame 802. As discussed above, in the particular example illustrated in FIG. 8B and discussed above, the bit sequence “011111” uniquely identifies the beginning of a data frame 802 and cannot occur elsewhere in data frame 802. Once synchronized, a receiver can then continuously receive data frames according to FIG. 8C and the transitions discussed in FIGS. 6A through 6D.

As illustrated in FIG. 2H, receiver 230 can process data from antenna 244 to demodulate data transmitted as discussed above. As discussed above, antenna 224 can be a triaxial antenna. The signals from antennas 234 and 236 are processed by AFE 240 and digitized to input to digital processing 242. As discussed above, much of the demodulation process can be achieved in digital processing 242.

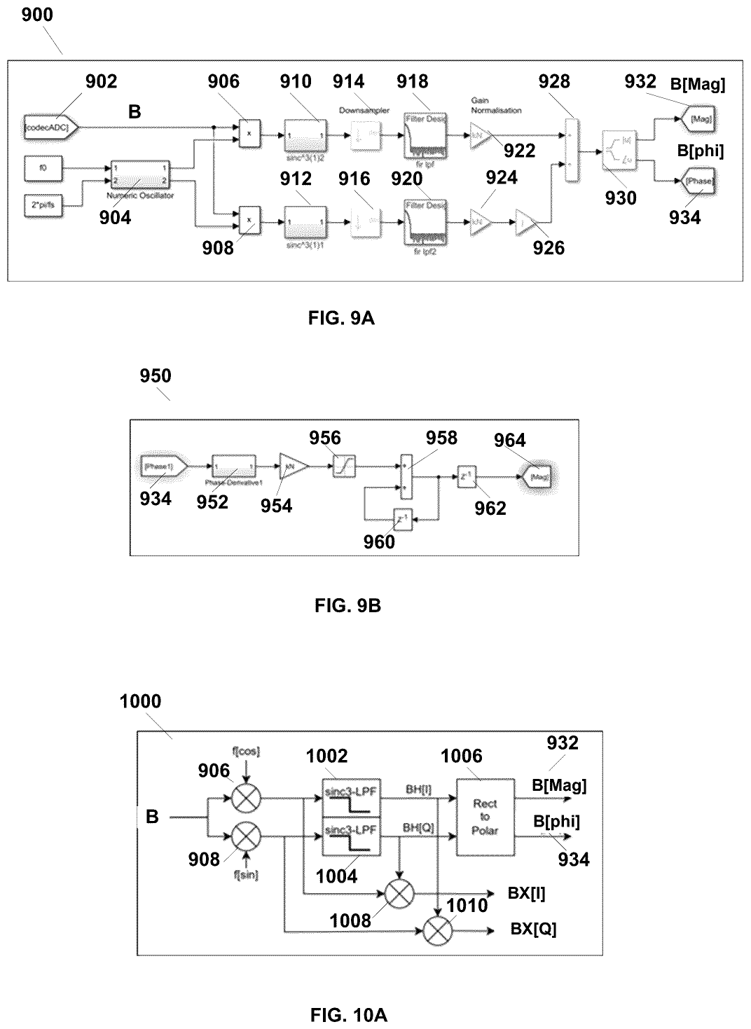

FIGS. 9A and 9B illustrate an example of phase coherent narrow band digital signal processing, which determines a magnitude and phase of one of the three signals from antenna 244 illustrated in FIG. 2H (i.e. BH1, BH2, and BV). FIG. 9A illustrates a narrow band decimating filter 900. FIG. 9B illustrates a local oscillator tracking circuit 950 that can be used with filter 900 of FIG. 9A.

As illustrated in FIG. 9A, an analog-to-digital converter (ADC) 902, which is part of the AFE of AFE 310, provides digital data from a given CODEC ADC channel from one of the signals BH1, BV, or BH2, here labeled B. The remaining components illustrated in FIG. 9A are aspects of one of the corresponding one of the signal processing 242 as illustrated in FIG. 2G. It should be noted that other antennas in wand 232 may include antennas that produce any number of magnetic signals that can be processed in a similar fashion as that described here.

The sampling rate at ADC 902 can be anything from 10 kHz to 192 kHz—the typical bands for a Sigma Delta Audio Codec. A numerical oscillator 904 can provide stable and phase-locked sine and cosign outputs at the carrier frequency f₀. Numeric oscillator 904 can operate similar to that described in U.S. Pat. No. 4,285,044. As shown in FIG. 9A, the digitized data signal from ADC 902 is mixed with a sine output of numeric oscillator 904 in mixer 906 and mixed with a cosine output of numeric oscillator 904 in mixer 908. Consequently, the output signals from mixers 906 and 908 provide in-phase and quadrature signals for processing. The algorithm exhibited in FIG. 9A, therefore, uses complex signals (In Phase and Quadrature Phase), which allows phase information to be carried through to the output.

The signals from mixers 906 and 908 are then down sampled. FIG. 9A illustrates a SINC3 decimating stage. In the decimating stage, the output signal from mixer 906 is processed through a SINC3 filter 910, a down sampler 914, and a low-pass filter 918. Furthermore, the output signal from mixer 908 is processed through a SINC3 filter 912, a down sampler 916, and a low-pass filter 920. In some embodiments, the down sampling bandwidth, for example, can be in the region of 50 Hz to 150 Hz, which is suitable for user interface 314.

Low-pass filters 918 and 920 can both be finite impulse response (FIR) filters that define the overall frequency response and bandwidth. For example, in some embodiments the frequency response of the FIR filters can be set to about 1 Hz. As is further illustrated in FIG. 9A, the output signal from filter 918 is input to amplifier 922 and the output signal from filter 920 is input to amplifier 924. Amplifiers 922 and 924 provide gain normalization. As is further illustrated in FIG. 9A, the output signal from amplifier 924 is inverted in inverter 926. The in-phase and quadrature signals from amplifier 922 and inverter 926, respectively, are input to combiner 928. The combined signal is input to processing block 930 where magnitude 932 and phase 934 are calculated from the in-phase and quadrature signals input to combiner 928. As shown in FIG. 2H, signals 932 and 934 are input to locate processing 258 and, combined with similar signals from other antennas in wand 232, is used to locate underground line 112.

FIG. 9B illustrates a local oscillator tracker 950 that can be used with decimating filter 900. Local oscillator tracker 950 forms a closed loop integral control law, the output of which adjusts the numeric oscillator 904 by a small amount until the error is negligible. This allows the receiver to be frequency locked to the transmission waveform and is important for the data encoding scheme described in further detail below.

As illustrated in the example local oscillator tracker 950 illustrated in FIG. 9B, the phase output signal 934 from decimating filter 900 is differentiated in phase derivative block 952. The result of block 952 is amplified in amplifier 954 and the result in input to integrator 956. The result of integrator 956 is input to a combiner 958. The output signal from combiner 958 is delayed in delay 960 and combined with the output signal from integrator 956 in combiner 958. The output signal from combiner 958 is again delayed in delay 962 and output to error correction 964. Error correction 964 can be input to numeric oscillator 904 illustrated in FIG. 9A to adjust the average frequency f₀ so that the average overall phase is minimal.

With the modulation scheme illustrated in FIGS. 6A through 6D above, local oscillator tracker 950 will move the oscillators to the effective average of the two frequency components:

$${F}_{avge} = \frac{2. {F}_{LOW} . {F}_{High}}{{F}_{LOW} + {F}_{High}}$$

As discussed above, the average of the frequency signals according to the modulation scheme illustrated in FIGS. 6A through 6D, the average frequency F_{avge} is the nominal frequency fₙₒₘ of the locating signal tone.

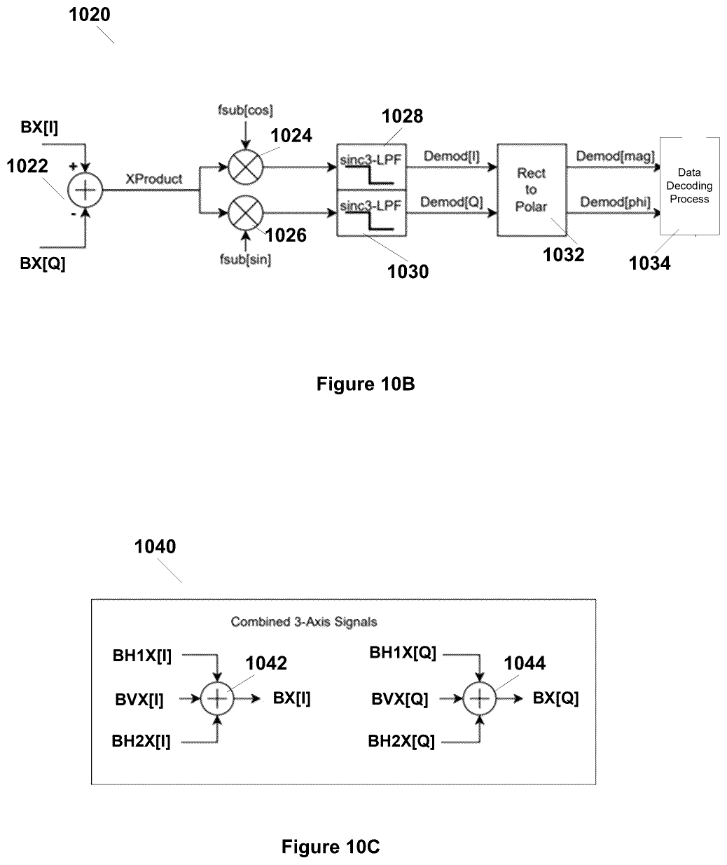

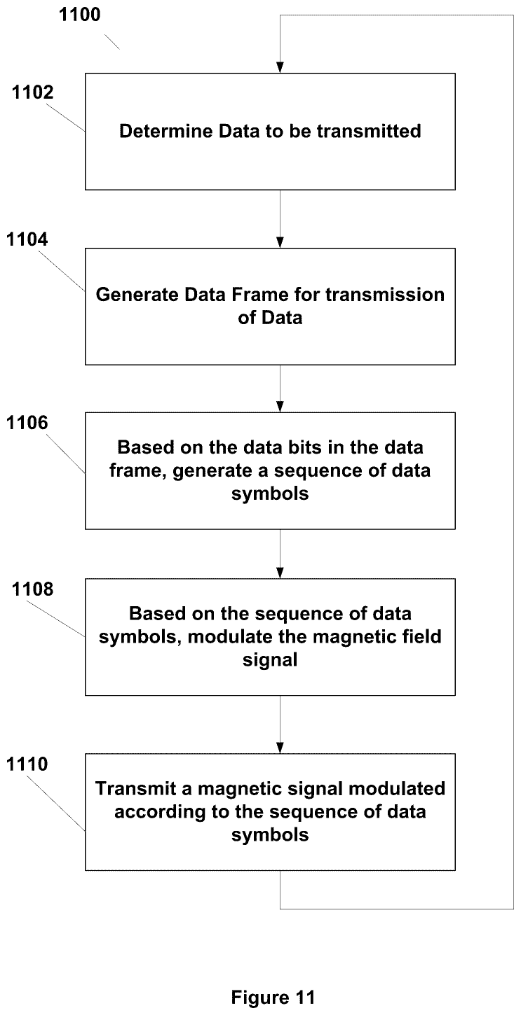

Demodulation of data transmitted by embodiments of the present disclosure is illustrated in FIGS. 10A through 10C. FIG. 10A illustrates a first stage 1000 of the demodulation process. First stage 1000 works with narrow band decimating filter 900 as illustrated in FIG. 9A. As shown in FIG. 9A, the digitized signal B, which one of the signals from an antenna such as antenna 244, is input to multipliers 906 and 908 and mixed with a cosine and sine signal to generate in-phase and quadrature signals. The signal from multiplier 906 is input to SINC3 decimator 1002, which includes SINC3 filter 910, down sampler 914, and low-pass filter 918 as illustrated in FIG. 9A. The signal from multiplier 908 is input to SINC3 decimator 1004, which includes SINC3 filter 912, down sampler 916, and low-pass filter 920 as illustrated in FIG. 9A. Processor 1006, rectifier and polar compute, represent elements 922, 924, 926, 928, and 930 illustrated in FIG. 9A. As discussed previously, processor 1006 outputs the magnitude and phase of the signal B (B [mag] 932 and B [phi] 934) for further processing.

The first stage 1000 of the demodulation uses a simple cross multiply to generate a sub-carrier channel effectively an intermediate tone, labelled BX [I] and BX [Q]. As is illustrated in FIG. 10A, the output signal from multiplier 906 is input to multiplier 1008 and mixed with the output signal from SINC3 decimator 1002 to form the output signal BX [I]. Similarly, the output signal from multiplier 908 is input to multiplier 1010 and mixed with the output signal from SINC3 decimator 1004 to form the output signal BX [Q].

The data encoding scheme described herein can be considered a frequency shift key arrangement. Consequently, the phase domain of the modulation appears as an orthogonal signal as represented by a Phasor on the Argand diagram. Accordingly, the demodulation uses a Vector Cross product of the Cartesian components as shown in FIG. 10B. As illustrated in the example of second stage 1020, the signals BX [I] and BX [Q] illustrated in FIG. 10A are input to vector cross product 1022 to form a cross product signal. The cross product signal is then input to multiplier 1024 and multiplier 1026. In multiplier 1024 the cross product signal is mixed with the cosine signal f_{sub} [cos] and in multiplier 1026 the cross product signal is mixed with the sine signal f_{sub} [sin]. The signals f_{sub} [cos] and f_{sub} [sin] are generated by a numeric oscillator that is running at the sub-carrier frequency. In this example it is notionally, the sub-carrier frequency f_{sub} is the average, or nominal, frequency f_{avg}/M. In the particular examples illustrated here, as illustrated above in FIGS. 4A and 4B, M=16. Consequently, in the specific examples discussed above, the sub-carrier frequency can be given by

$${f}_{sub} = {f}_{avg} / 16$$

The output signal from multiplier 1024 is input to a SINC3 decimating filter 1028. The output signal from multiplier 1026 is input to a SINC3 decimating filter 1030. The output signals from SINC3 decimating filters 1028 and 1030, demod [I] and demod [Q] respectively, is input to rectifier circuit 1032. As illustrated in FIG. 10B, rectifier circuit 1032 outputs the demodulated magnitude and phase.

The bandwidth used in the demodulation stage is set accurately to ensure it is sufficiently wide to pass the data-information bandwidth without degradation. The demodulated magnitude is fed to the data decoding process 1034 to determine the phase characteristics as described in FIGS. 4A and 4B. Data decoding processor 1034 can then determine N-state or P-state characteristics, and ultimately the transitions between data symbols as described in FIGS. 6A through 6D.

The example illustrated in FIGS. 10A and 10B use a single magnetic field signal B, which can be one of the signals from antenna 244 (BH1, BH2, and BV). As discussed above, antenna 224 can be a triaxial antenna that includes three orthogonally oriented coils for measuring the magnetic field in three orthogonal directions. As illustrated in FIG. 2H, antenna 244 includes two orthogonal horizontal coils that produces signals BH1 and BH2 related to the magnetic field strength in two orthogonal horizontal directions and a vertically oriented coil that produce signal BV related to the magnetic field strength in the vertical direction. In some embodiments, in order to improve the detection of the data signal, all of the signals from antenna 244 can be used to demodulate the data signal in FIG. 10B.

Each of the signals BH1, BH2, and BV from antenna 244 can be processed through parallel first stages 1000 as illustrated in FIG. 10A. This provides signals BH1X [I] and BH1X [Q] corresponding to input signal BH1, BH2X [I] and BH2X [Q] corresponding to input signal BH2, and signals BVX [I] and BVX [Q] corresponding to input signal BV. BHIX [I] is the In-Phase component of the Sub-Carrier tone derived from a horizontal-oriented coil of antenna 244. BVX [I] is the In-Phase component of the Sub-Carrier taken from the vertically oriented coil of antenna 244. BH2X [I] is the In-Phase component of second horizontally oriented coil of antenna 244. BH1X [Q], BVX [Q] and BH2X [Q] are the quadrature components of signals BH1, BV, and BH2, respectively.

As is illustrated in FIG. 10C, the in-phase signals BHIX [I], BVX [I], and BH2X [I] are combined in summer 1042 to produce a combined signal BX [I]. The quadrature signals BH1X [Q], BVX [Q], and BH2X [Q] are combined in summer 1044 to produce a combined signal BX [Q]. The combined signals BX [I] and BX [Q] are input into second stage 1020 as indicated in FIG. 10B. Consequently, FIG. 10C allows a method of performing the demodulation on all three (3) axes as measured in antenna 334 without causing contention or any loss of signal-to-noise ratio.

On first inspection, it may be thought that the summation of signals as illustrated in FIG. 10C would add noise to the demodulation process as a consequence of increasing the overall noise aperture of the system. This has been shown not to be the case, the orthogonal nature of the vector cross product affected by cross product 1022 handles this effectively and allows the demodulation process to run smoothly regardless of which antenna may be carrying the dominant signal.

FIG. 11 illustrates operation 1100 of a transmitter 300 as illustrated in FIGS. 3A-3E according to some embodiments of the present disclosure. As illustrated, operation 1100 may be executed by processor 310, at least partially according to instructions stored in a memory of processor 310. In step 1102 of processor 1100, processor 310 receives parameters from sensors 316 as well as data from line driver 320 and power source 312 as discussed above. In step 1104, a data frame such as data frame 802 illustrated in FIG. 8A is assembled to include data representing the parameters received in step 1102. In step 1106, based on the data frame 802 generated in step 1104, a sequence of data symbols is generated according to that described in FIG. 8B. In step 1108, the sequency of frequency modulations as illustrated in FIGS. 4A and 4B and FIGS. 5A and 5B corresponding to the data symbol sequence generated in step 1108 is determined. Finally, in step 1110, processor 344 provides input to driver 346 to drive antenna 348 to transmit the magnetic symbol according to the modulation determined in step 1108. As should be understood, the timing of these sequences is such that a continuous sequence of data frames 802 is transmitted on the magnetic signal generated by sonde 340.

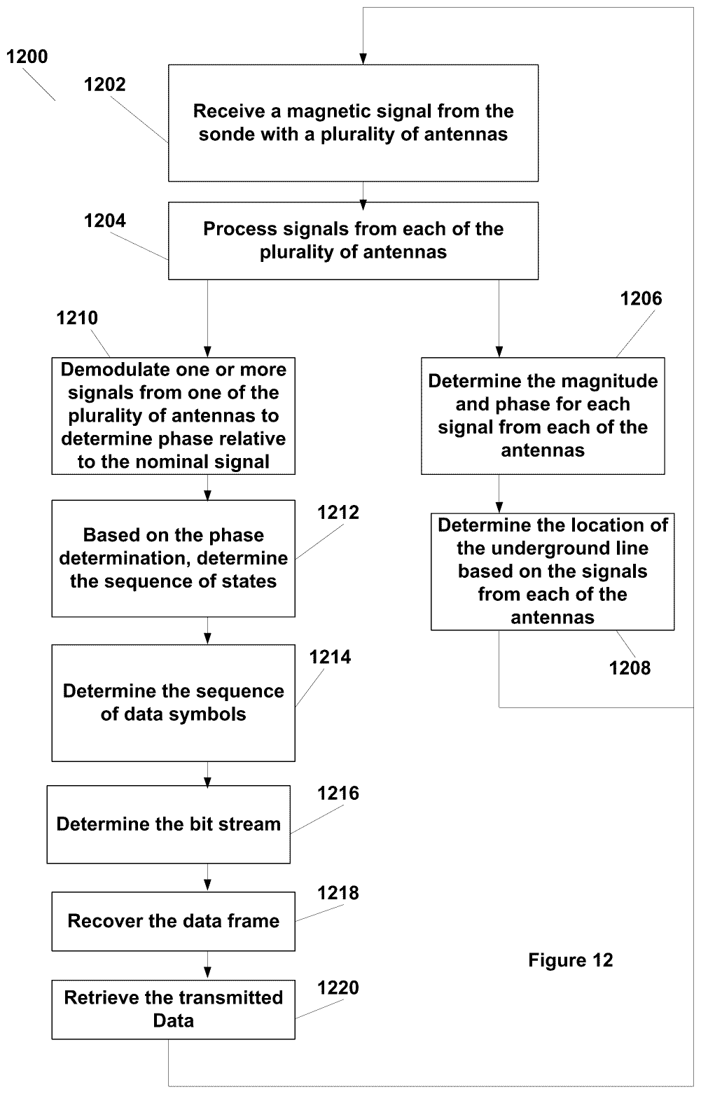

FIG. 12 illustrates operation 1200 of a receiver 300 according to some embodiments of the present disclosure. Receiver 230, as illustrated in FIGS. 2G and 2H, includes components as illustrated in 9A, 9B, 10, 10B, and 10C. In particular, these operations may be executed by various aspects of digital processor 242.

As shown in FIG. 12, in step 1202 of operation 1200 receiver 230 receives the magnetic signal emitted by line 112 with a plurality of antennas. As illustrated in FIGS. 2G and 2H, each of the plurality of antennas may generate one or more signals associated with the magnetic field strength and direction at receiver 230. For example, as is illustrated in FIG. 2H, one or more of the antennas, for example antenna 244, can be a triaxial antenna that receives signals according to the magnetic field strengths in two orthogonal horizontal directions and one vertical direction. In step 1204, the signals from each of the antennas are processed and digitized and input to digital processor 242, which performs the remainder of the operations in operation 1200.

As illustrated in FIG. 12, digital processor 242 can determine the magnitude and phase of each of the signals from each of the antennas in step 1206 as is described with FIGS. 9A and 9B. In step 1208, receiver 230 can then determine the physical location of line 230 based on the signals received from the plurality of antennas.

Steps 1210 through 1218 describe demodulating the received signals from the antennas to recover the digital bit stream that was modulated onto the magnetic signal emitted by line 112. In step 1210, one or more signals from one of the antennas is demodulated as illustrated in FIGS. 10A through 10C to determine the phase relative to the nominal signal. In step 1212, from the phase determination, individual states are determined. As is discussed above, the states are M cycles designating an N-state or a P-state. In step 1212, receiver 230 detects the transition from an N-state to a P-state or a P-state to an N-state, which indicates the beginning of individual states and from which the sequence of individual states can be determined.

In step 1214, the sequence of data symbols as illustrated in FIG. 8B can be determined. Locating a 0 bit transition as has been accomplished in step 1214 also indicates the start of a data symbol. Consequently, the sequence of data symbols can be determined.

In step 1216, from the sequence of data symbols, the bit stream can be determined. From a 0 transition, setting the demarcation between two states and also the demarcation between two data symbols, the data symbols are recovered. In step 1218, receiver 230 can then locate the synchronization field “11111” that indicates the beginning of a data frame 802. Once that is located, receiver 230 then recovers the series of data frames 802 that are being transmitted by transmitter 230.

In the preceding specification, various embodiments have been described with reference to the accompanying drawings. It will, however, be evident that various modifications and changes may be made thereto, and additional embodiments may be implemented, without departing from the broader scope of the invention as set for in the claims that follow. The specification and drawings are accordingly to be regarded in an illustrative rather than restrictive sense.

What is claimed is:

1. A method of transmitting digital data from a transmitter in a line location system, comprising:
determining data to be transmitted;
generating a bit stream based on the data to be transmitted; and
driving an underground line to emit a magnetic field that is modulated with the bit stream, the magnetic signal having a nominal frequency and being formed of a first signal having a high frequency and a second signal having a low frequency, the high frequency being higher than the nominal frequency and the low frequency being lower than the nominal frequency, the nominal frequency being the average frequency of the magnetic signal,
wherein the bit stream is modulated onto the magnetic signal by encoding the bit stream into the magnetic signal, where each bit in the bit stream is represented by a transition between adjoining data symbols, each of the data symbols is formed of K repetitions of one of a first state or a second state, where the first state of the pair of states includes M/2 cycles of the nominal frequency with a signal at the high frequency and M/2 cycles of the nominal frequency with a signal at the low frequency, and where a second state of the pair of states includes signals complementary to the first state.

2. The method of claim 1, wherein transitions representing a digital one bit is encoded with a first data symbol of the adjoining symbols formed with the first state and a second data symbol of the adjoining symbols formed with the first state or the first data symbol formed with the second state and the second data symbol formed with the second state.

3. The method of claim 2, wherein transitions representing a digital zero bit is encoded with the first data symbol formed with the first state and the second data symbol formed with the second state or the first data symbol formed with the second state and the second data symbol formed with the first state.

4. The method of claim 3, wherein the bit stream is formed into a continuous sequence of data frames, each data frame being formed with a separator followed by a synchronization field and one or more data fields, the synchronization field and the one or more data fields separated by a separator.

5. The method of claim 4, wherein the one or more of the data fields is encoded with one or more parameters, the each of the one or more parameters include transmitter connection status, temperature, battery state-of-charge, transmitter temperature, vibration, or current strength.

6. The method of claim 4, wherein the frame further includes a cyclic redundancy check (CRC) field separated from the last data field by a separator.

7. The method of claim 4, where the separator bits are zero and the synchronization bits are all ones.

8. The method of claim 7, wherein the one or more data fields includes a first data field, a second data field, and a third data field.

9. The method of claim 1, wherein the first state includes M/4 cycles of signal at the high frequency followed by M/2 cycles of signal at the low frequency and then M/4 cycles of signals at the high frequency; and wherein the second state includes M/4 cycles of signal at the low frequency followed by M/2 cycles of signal at the high frequency and then M/4 cycles of signals at the low frequency.

10. A method of transmitting data from a transmitter coupled to an underground line, comprising:
measuring parameters associated with the transmitter with sensors in the transmitter;
encoding the parameters into a data frame, the data frame having a sequence of bits, the data frame including a separator followed by a synchronization field and one or more data fields separated by separators;
determining a sequence of data symbols to represent the data frame, each of the sequence of bits in the data frame being represented by transitions between adjacent data symbols in the sequence of data symbols, the data symbols each being formed by K repetitions of a first state or formed by K repetitions of a second state, where the first state includes M/2 cycles of a nominal frequency with a high frequency signal at a high frequency and M/2 cycles of the nominal frequency with a low frequency signal at a low frequency, the high frequency being higher than the nominal frequency and the low frequency being lower than the nominal frequency such that the average signal is at the nominal frequency; and
driving the underground line to emit a magnetic signal formed with the sequency of data symbols.

11. The method of claim 10, wherein transitions representing a digital one bit is encoded with a first data symbol of the adjoining symbols formed with the first state and a second data symbol of the adjoining symbols formed with the first state or the first data symbol formed with the second state and the second data symbol formed with the second state.

12. The method of claim 11, wherein transitions representing a digital zero bit is encoded with the first data symbol formed with the first state and the second data symbol formed with the second state or the first data symbol formed with the second state and the second data symbol formed with the first state.

13. The method of claim 12, wherein the bit stream is formed into a continuous sequence of data frames, each data frame being formed with a separator followed by a synchronization field and one or more data fields, the synchronization field and the one or more data fields separated by a separator.

14. The method of claim 13, wherein the one or more parameters encoded into the one or more data fields are chosen from the set consisting of transmitter connection status, temperature, battery state-of-charge, transmitter temperature, vibration, and current strength.

15. The method of claim 14, wherein the frame further includes a cyclic redundancy check (CRC) field separated from the last data field by a separator.

16. The method of claim 14, where the separator bits are zero and the synchronization bits are all ones.

17. The method of claim 14, wherein the one or more data fields includes a first data field, a second data field, and a third data field.

18. The method of claim 12, wherein the first state includes M/4 cycles of signal at the high frequency followed by M/2 cycles of signal at the low frequency and then M/4 cycles of signals at the high frequency; and wherein the second state includes M/4 cycles of signal at the low frequency followed by M/2 cycles of signal at the high frequency and then M/4 cycles of signals at the low frequency.

19. A transmitter, comprising:
one or more sensors to measure parameters associated with the transmitter;
a line driver coupled to drive an underground line to transmit a magnetic signal; and
a processor coupled to the one or more sensors and the driver, the processor configured to
receive parameters associated with the transmitter;
encode the parameters into a data frame, the data frame having a sequence of bits, the data frame including a separator followed by a synchronization field and one or more data fields separated by separators;
determine a sequence of data symbols to represent the data frame, each of the sequence of bits in the data frame being represented by transitions between adjacent data symbols in the sequence of data symbols, the data symbols each being formed by K repetitions of a first state or formed by K repetitions of a second state, where the first state includes M/2 cycles of a nominal frequency with a high frequency signal at a high frequency and M/2 cycles of the nominal frequency with a low frequency signal at a low frequency, the high frequency being higher than the nominal frequency and the low frequency being lower than the nominal frequency such that the average signal is at the nominal frequency; and
communicate the input signal corresponding to the sequence of data symbols to the driver.

20. The transmitter of claim 19, wherein the first state includes M/4 cycles of signal at the high frequency followed by M/2 cycles of signal at the low frequency and then M/4 cycles of signals at the high frequency; and wherein the second state includes M/4 cycles of signal at the low frequency followed by M/2 cycles of signal at the high frequency and then M/4 cycles of signals at the low frequency.

21. A method of receiving digital data from a magnetic signal emitted by a line driven by a transmitter, comprising:
receiving a magnetic signal emitted by the under line, the magnetic signal having a nominal frequency and being formed of a first signal having a high frequency and a second signal having a low frequency, the high frequency being higher than the nominal frequency and the low frequency being lower than the nominal frequency, the nominal frequency being the average frequency of the magnetic signal;
digitizing the magnetic signal to provide a digitized magnetic signal; and
processing the digitized magnetic signal to recover a bit stream, where each bit in the bit stream is represented by a transition between adjoining data symbols, each of the data symbols is formed of K repetitions of one of a first state or a second state, where the first state of the pair of states includes M/2 cycles of the nominal frequency with a signal at the high frequency and M/2 cycles of the nominal frequency with a signal at the low frequency, and where a second state of the pair of states includes signals complementary to the first state.

22. The method of claim 21, wherein processing the digitized magnetic signal to recover the bit stream includes
demodulating the magnetic signal to determine phase relative to a nominal signal, the nominal signal being at the nominal frequency;
determining a sequence of data symbols; and
determining the transitions between adjacent data symbols to determine the bit stream.

23. The method of claim 22, wherein demodulating the magnetic signal includes
mixing the digitized magnetic signal with a sine and a cosine wave at a carrier frequency to obtain an in-phase and a quadrature signal;
filtering the in-phase and the quadrature signal with decimator filters;
mixing output signals from the decimator filters with the in-phase and quadrature signals to generate sub-carrier channel signals BX [I] and BX [Q];
combining the sub-carrier signals BX [I] and BX [Q] to form a cross product signal;
mixing the cross product signal with a sine and cosine signal at a subcarrier frequency;
filtering signals from the from the cross-product with a decimating filter to provide demodulated signals; and
generating demodulated magnitude and phase signals from the demodulated signals.

24. The method of claim 23, further including combining the sub-carrier channel signals BX [I] and BX [Q] from a plurality of magnetic signals before combining to form the cross product signal.

25. The method of claim 24, wherein receiving the magnetic signal includes receiving magnetic signals from a triaxial antenna, the triaxial antenna producing signals related to the magnetic field in two orthogonal horizontal directions and a vertical direction, and wherein combining the sub-carrier channel signals includes
generating sub-carrier channel signals for each of the signals; and
combining the sub-carrier channel signals for each of the signals to generate the combined sub-carrier channel signals.

26. The method of claim 25, wherein transitions representing a digital one bit is encoded with a first data symbol of the adjoining symbols formed with the first state and a second data symbol of the adjoining symbols formed with the first state or the first data symbol formed with the second state and the second data symbol formed with the second state.

27. The method of claim 26, wherein transitions representing a digital zero bit is encoded with the first data symbol formed with the first state and the second data symbol formed with the second state or the first data symbol formed with the second state and the second data symbol formed with the first state.

28. The method of claim 27, wherein the bit stream is formed into a continuous sequence of data frames, each data frame being formed with a separator followed by a synchronization field and one or more data fields, the synchronization field and the one or more data fields each separated by a separator.

29. The method of claim 28, where the separator is a zero bit and the synchronization field includes all ones.

30. The method of claim 29, wherein the frame further includes a cyclic redundancy check (CRC) field separated from the last data field by a separator.

31. The method of claim 30, wherein the one or more data fields include a first data field, a second data field, and a third data field.

32. The method of claim 21, wherein the first state includes M/4 cycles of signal at the high frequency followed by M/2 cycles of signal at the low frequency and then M/4 cycles of signals at the high frequency; and wherein the second state includes M/4 cycles of signal at the low frequency followed by M/2 cycles of signal at the high frequency and then M/4 cycles of signals at the low frequency.

33. A receiver, comprising:
one or more antennas, each of the one or more antennas producing one or more signals related to a magnetic signal emitted from an underground line;
an analog front end that receives and digitizes each of the one or more signals from each of the one or more antennas; and
a digital processor configured to receive the digitized signals from the analog front end and recovering digital data modulated onto the magnetic field generated by the sonde,
wherein the magnetic signal is modulated according to a bit stream, the magnetic signal having a nominal frequency and being formed of a first signal having a high frequency and a second signal having a low frequency, the high frequency being higher than the nominal frequency and the low frequency being lower than the nominal frequency, the nominal frequency being the average frequency of the magnetic signal, and
wherein the bit stream is modulated onto the magnetic signal by encoding the bit stream into the magnetic signal, where each bit in the bit stream is represented by a transition between adjoining data symbols, each of the data symbols is formed of K repetitions of one of a first state or a second state, where the first state of the pair of states includes M/2 cycles of the nominal frequency with a signal at the high frequency and M/2 cycles of the nominal frequency with a signal at the low frequency, and where a second state of the pair of states includes signals complementary to the first state.

34. The receiver of claim 33, wherein the digital processor is configured to identify transitions representing a digital one bit that is encoded with a first data symbol of the adjoining symbols formed with the first state and a second data symbol of the adjoining symbols formed with the first state or the first data symbol formed with the second state and the second data symbol formed with the second state.

35. The receiver of claim 34, wherein the digital processor is configured to identify transitions representing a digital zero bit that is encoded with the first data symbol formed with the first state and the second data symbol formed with the second state or the first data symbol formed with the second state and the second data symbol formed with the first state.

36. The receiver of claim 35, wherein the bit stream is formed into a continuous sequence of data frames, each data frame being formed with a separator followed by a synchronization field and one or more data fields, the synchronization field and the one or more data fields separated by a separator.

37. The receiver of claim 36, where the separator bits are zero and the synchronization bits are all ones.

38. The receiver of claim 37, wherein the frame further includes a cyclic redundancy check (CRC) field separated from the last data field by a separator.

39. The receiver of claim 38, further including reading pitch and roll data from the sonde and encoding the pitch and roll data into the one or more data fields.

40. The receiver of claim 33, wherein the first state includes M/4 cycles of signal at the high frequency followed by M/2 cycles of signal at the low frequency and then M/4 cycles of signals at the high frequency; and wherein the second state includes M/4 cycles of signal at the low frequency followed by M/2 cycles of signal at the high frequency and then M/4 cycles of signals at the low frequency.

41. The receiver of claim 33, wherein the digital processor recovers digital data based on a single signal from one of the antennas.

42. The receiver of claim 33, wherein one of the antennas is a triaxial antenna and the digital processor is configured to recover digital data based on three signals from the triaxial antenna.
